(19) United States
(12) Patent Application Publication
(10) Pub. No.: US 2019/0196283 A1
(43) Pub. Date: Jun. 27, 2019

(54) SUBSTRATE FOR DISPLAY DEVICE AND DISPLAY DEVICE

(71) Applicant: SHARP KABUSHIKI KAISHA, Osaka (JP)

(72) Inventor: MASAHIRO YOSHIDA, Sakai City (JP)

(21) Appl. No.: 16/232,075

(22) Filed: Dec. 26, 2018

(30) Foreign Application Priority Data
Dec. 27, 2017 (JP) 2017-251138

(51) Int. Cl. G02F 1/1362; H01L 27/12; G02F 1/1343; G02F 1/1368

(52) U.S. Cl. CPC G02F 1/136213; H01L 27/124; G02F 1/134336; H01L 27/1255; G02F 1/133788; G02F 1/1368; G02F 1/136286; G02F 1/13439; G02F 2201/52; H01L 27/1248

(57) ABSTRACT

A substrate for a display device includes a pixel electrode, at least two signal lines, a first auxiliary capacitor, a second auxiliary capacitor, and an auxiliary capacitor connecting section. The at least two signal lines sandwich the pixel electrode, supply a signal to the pixel electrode and extend in an extending direction of a signal line. The first auxiliary capacitor extends and crosses the pixel electrode and the signal lines and overlaps the signal lines via a first interlayer insulator and overlaps the pixel electrode via a second interlayer insulator. The second auxiliary capacitor is disposed spaced from the first auxiliary capacitor with respect to the extending direction of the signal line and overlaps the pixel electrode via the second interlayer insulator and does not overlap one of the at least two signal lines. The auxiliary capacitor connecting section connects the first auxiliary capacitor and the second auxiliary capacitor.

### CROSS REFERENCE TO RELATED APPLICATION

This application claims priority from Japanese Patent Application No. 2017-251138 filed on Dec. 27, 2017. The entire contents of the priority application are incorporated herein by reference.

### TECHNICAL FIELD

The technology described herein relates to a substrate for a display device and a display device.

### BACKGROUND

A liquid crystal display device includes drain signal lines that supply an image signal to each of the pixels and a disconnection prevention line that prevents disconnection of the drain signal lines. The disconnection prevention line is connected to each end of the disconnected drain line such that an image signal can be supplied to the drain signal line. Such a liquid crystal display device is described in Unexamined Japanese Patent Application Publication No. 2001-13517.

According to such a liquid crystal display device including the disconnection prevention line that is connected to the drain signal line, if the drain signal line is disconnected, the disconnection prevention line functions as a branch circuit such that the image signal can be supplied to an end side opposite from a signal supply side end of the drain signal line through the disconnected drain signal line. The liquid crystal display device may include an auxiliary capacitor line to keep a potential of the pixel electrode that is charged according to the image signal that is supplied to the drain signal line. The auxiliary capacitor line extends along the gate signal line and crosses the drain signal line and the pixel electrode. A parasitic capacitance may be created between the drain signal line and the auxiliary capacitor line that cross each other and blunting may be caused in the image signal that is transferred through the drain signal line. Particularly, according to the increase in size and resolution of the liquid crystal display device, the crossing points of the drain signal lines and the auxiliary capacitor lines tend to be increased and therefore, blunting of an image signal is more likely to be caused.

### SUMMARY

The technology described herein was made in view of the above circumstances. An object is to achieve less occurrence of signal blunting.

A substrate according to the technology described herein includes a pixel electrode, at least two signal lines, a first auxiliary capacitor, a second auxiliary capacitor, and an auxiliary capacitor connecting section. The at least two signal lines sandwich the pixel electrode, supply a signal to the pixel electrode, and extend in an extending direction of a signal line. The first auxiliary capacitor extends and crosses the pixel electrode and the at least two signal lines and overlaps the at least two signal lines via a first interlayer insulator and overlaps the pixel electrode via a second interlayer insulator. The second auxiliary capacitor is disposed spaced from the first auxiliary capacitor with respect to the extending direction of the signal line and overlaps the pixel electrode via the second interlayer insulator and does not overlap one of the at least two signal lines. The auxiliary capacitor connecting section connects the first auxiliary capacitor and the second auxiliary capacitor.

According to such a configuration, the pixel electrode is supplied with the signal transferred through the signal line and charged at a predetermined potential. The first capacitor and the second auxiliary capacitor connected by the auxiliary capacitor connecting section create an electrostatic capacitance with the pixel electrode overlapping each of the first auxiliary capacitor and the second auxiliary capacitor via the second interlayer insulator such that the potential of the charged pixel electrode can be maintained. The first auxiliary capacitor extends and crosses the signal lines that sandwich the pixel electrode so as to be supplied with a potential from the signal supply source. The second auxiliary capacitor is supplied with a potential from the first auxiliary capacitor through the auxiliary capacitor connecting section. The second auxiliary capacitor does not overlap at least one of the two signal lines. According to such a configuration, the parasitic capacitance that may be created between the signal line and the second auxiliary capacitor can be reduced compared to a configuration that the second auxiliary capacitor crosses the two signal lines. As a result, blunting is less likely to be caused in the signal transferred through the signal line and it is preferable for increasing a size and enhancing resolution.

The technology described herein achieves less occurrence of signal blunting.

### BRIEF DESCRIPTION OF THE DRAWINGS

FIG. 1 is a schematic plan view of a liquid crystal panel, a flexible board, and a printed circuit board of a liquid crystal display device according to a first embodiment.

FIG. 2 is a schematic plan view illustrating a connection structure of auxiliary capacitor trunk lines and auxiliary capacitor lines in a display area of the liquid crystal panel.

FIG. 3 is a plan view illustrating a structure of lines in the display area of the liquid crystal panel.

FIG. 4 is a cross-sectional view of the liquid crystal panel taken along line A-A in FIG. 3.

FIG. 5 is an enlarged plan view illustrating a vicinity of a TFT and the auxiliary capacitor line in the display area of the liquid crystal panel.

FIG. 6 is an enlarged plan view illustrating the vicinity of the TFT and an auxiliary capacitor electrode in the display area of the liquid crystal panel.

FIG. 7 is a cross-sectional view taken along line B-B in FIG. 5.

FIG. 8 is a cross-sectional view taken along line C-C in FIG. 6.

FIG. 9 is a pattern of a third metal film included in an array substrate of the liquid crystal panel.

FIG. 10 is a cross-sectional view taken along line D-D in FIG. 5.

FIG. 11 is a cross-sectional view taken along line E-E in FIG. 6.

FIG. 12 is a cross-sectional view taken along line F-F in FIG. 6.

FIG. 13 is a schematic plan view illustrating a structure of lines in a display area of a liquid crystal panel according to a second embodiment.

FIG. 14 is a plan view illustrating a pattern of a transparent electrode film included in an array substrate of the liquid crystal panel.

FIG. 15 is a plan view illustrating a pattern of a third metal film included in the array substrate of the liquid crystal panel.

FIG. 16 is a schematic plan view illustrating a structure of lines in a display area of a liquid crystal panel according to a third embodiment.

FIG. 17 is a cross-sectional view taken along line G-G in FIG. 16.

FIG. 18 is a plan view illustrating a pattern of a transparent electrode film included in an array substrate of the liquid crystal panel.

FIG. 19 is a plan view illustrating a pattern of a third metal film included in the array substrate of the liquid crystal panel.

FIG. 20 is a schematic plan view illustrating a structure of lines in a display area of a liquid crystal panel according to a fourth embodiment.

FIG. 21 is a schematic plan view illustrating a structure of lines in a display area of a liquid crystal panel according to a fifth embodiment.

FIG. 22 is a plan view illustrating a pattern of a transparent electrode film included in an array substrate of the liquid crystal panel.

FIG. 23 is a plan view illustrating a pattern of a third metal film included in the array substrate of the liquid crystal panel.

FIG. 24 is a plan view illustrating a pattern of a third metal film included in an array substrate of a liquid crystal panel according to a sixth embodiment.

FIG. 25 is a schematic plan view illustrating a connection structure of auxiliary capacitor trunk lines and auxiliary capacitor lines in a display area of the liquid crystal panel.

FIG. 26 is a plan view illustrating a pattern of a third metal film included in an array substrate of a liquid crystal panel according to a seventh embodiment.

### DETAILED DESCRIPTION

### First Embodiment

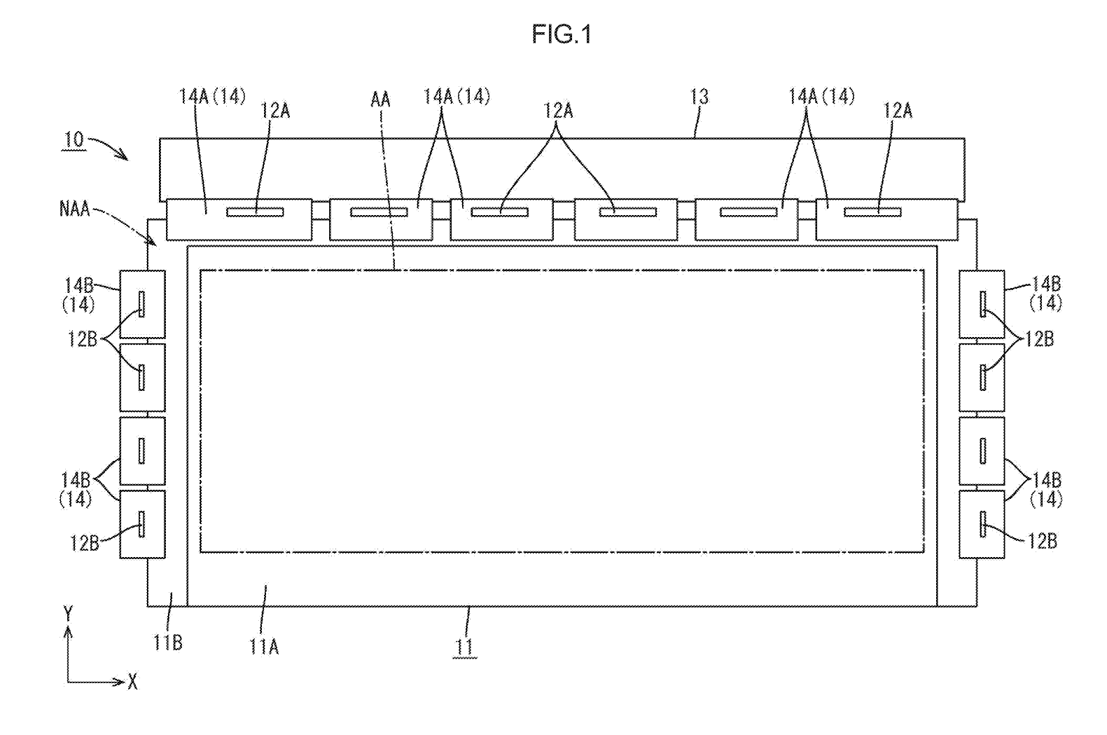

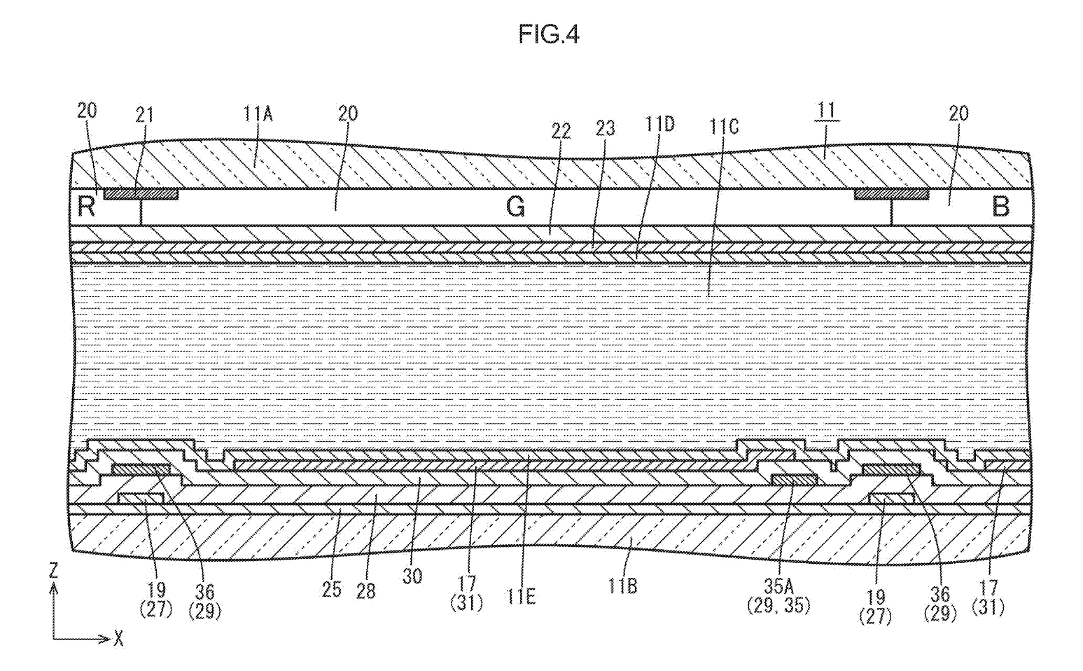

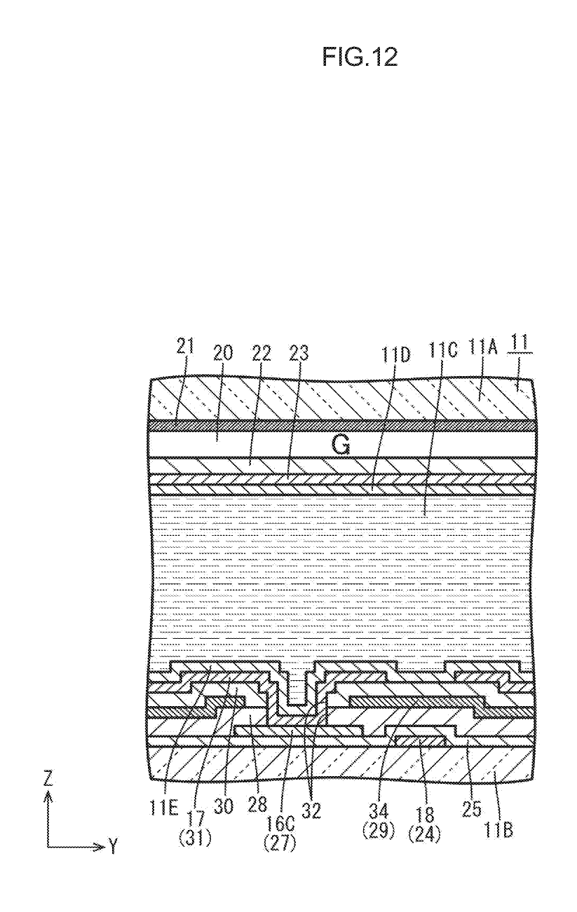

A first embodiment of the present technology will be described with reference to FIGS. 1 to 12. A liquid crystal display device 10 will be described as an example. X-axis, the Y-axis and the Z-axis may be present in the drawings. The axes in each drawing correspond to the respective axes in other drawings. The vertical direction is defined based on FIGS. 4, 7, 8, 10 to 12. An upper side and a lower side in the drawings correspond to a front side and the back side of the liquid crystal display device 10, respectively.

As illustrated in FIG. 1, the liquid crystal display device 10 includes a liquid crystal panel (display device) 11 on which images appear and a backlight unit (not illustrated) that is arranged behind the liquid crystal panel 11 and supplies light to the liquid crystal panel 11 for display. In this embodiment, the liquid crystal panel 11 has a screen size of 70 inches and a resolution of “7680*4320”, that is, so-called 8K resolution. The liquid crystal display device 10 further includes flexible boards 14 that are connected to an edge portion of the liquid crystal panel 11 and a printed circuit board 13 that is connected to some of the flexible boards 14. The flexible boards 14 and the printed circuit board 13 are directly or indirectly connected to the liquid crystal panel 11 to form one module component. The flexible boards 14, the printed circuit board 13, and the liquid crystal panel 11 configure a liquid crystal panel module (a display panel module). The liquid crystal panel 11 and the flexible boards 14 are connected to each other while having an anisotropic conductive film (ACF) therebetween and the flexible boards 14 are connected to the printed circuit board 13 with an anisotropic conductive film (ACF).

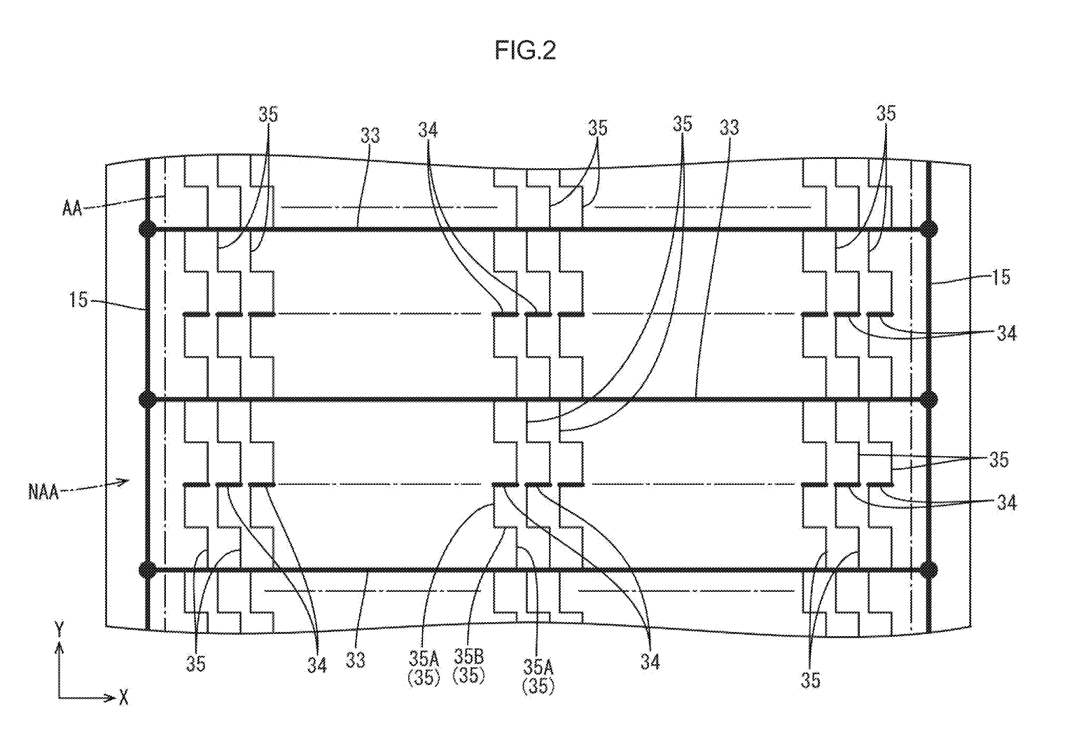

As illustrated in FIG. 1, the liquid crystal panel 11 has a rectangular shape la quadrangular shape) as a whole. The liquid crystal panel 11 includes a display area (an active area) AA configured to display an image and a non-display area (a non-active area) NAA outside the display area AA. The non-display area NAA has a plan view frame shape. The display area AA is a middle area of a plate surface (a display surface) of the liquid crystal panel 11. In FIG. 1, the outline of the display area AA is illustrated with a dashed line and the area outside the dashed line is the non-display area NAA. The liquid crystal panel 11 includes at least a glass substrates 11A, 11B and one on the front side (a front surface side) is a CF substrate (a counter substrate) 11A and another one on the rear side (a back surface side) is an array substrate (a substrate for a display device, an active matrix substrate, a TFT substrate) 11B. Polarizing plates (not illustrated) are attached to outer surfaces of the substrates 11A, 11B, respectively. The flexible board 14 includes a film substrate having insulation and flexibility and made of synthetic resin (for example, polyimide resin) and wiring on the film substrate. The flexible boards 14 include source-side flexible boards 14A that are connected to a long-side edge portion of the liquid crystal panel 11 that is the non-display area NAA and gate-side flexible boards 14B that are connected to short-side edge portions of the liquid crystal panel 11 that are the non-display area NAA. The source-side flexible boards 14A (six source-side flexible boards 14A) are arranged along one of the long-side edge portions (an upper one in FIG. 1) of the liquid crystal panel 11 at intervals with respect to the X-axis direction. Each of the source-side flexible boards 14A is connected to a source-side terminal (not illustrated) that is disposed on a long-side edge portion of the array substrate 11B. The source-side terminals are arranged at intervals along the X-axis direction in a mounting area of each source-side flexible board 14A. The source-side terminals are connected to a source line 19 extending from the display area AA. Each of the source-side flexible boards 14A is connected to a source driver (a display driving portion) 12A that supplies image signals to the source line 19. The gate-side flexible boards 14B (four on each short-side edge portion) are arranged at intervals in the Y-axis direction along two short-side edge portions of the liquid crystal panel 11. Each of the gate-side flexible boards 14B is connected to gate-side terminals (not illustrated) arranged on each of short-edge portion of the array substrate 11B. The gate-side terminals are arranged at intervals along the Y-axis direction in a mounting area of each gate-side flexible board 14B. The gate-side terminals are connected to a gate line extending from the display area. Each of the gate-side flexible boards 14B is connected to a gate driver (a display driving portion) 12B that supplies scan signals to a gate line 18. As illustrated in FIG. 2, auxiliary capacitor trunk lines (a signal supply source) 15 that are connected to auxiliary capacitor lines 33, which will be described later, are arranged in the non-display area NAA of the array substrate 11B. The auxiliary capacitor trunk line 15 extends along the Y-axis direction in a long-side portion of the non-display area NAA. The auxiliary capacitor trunk line 15 is supplied with a reference potential from one of the drivers 12A, 12B in FIG. 1 or from the printed circuit board 13 through the flexible boards 14 not through the drivers 12A, 12B.

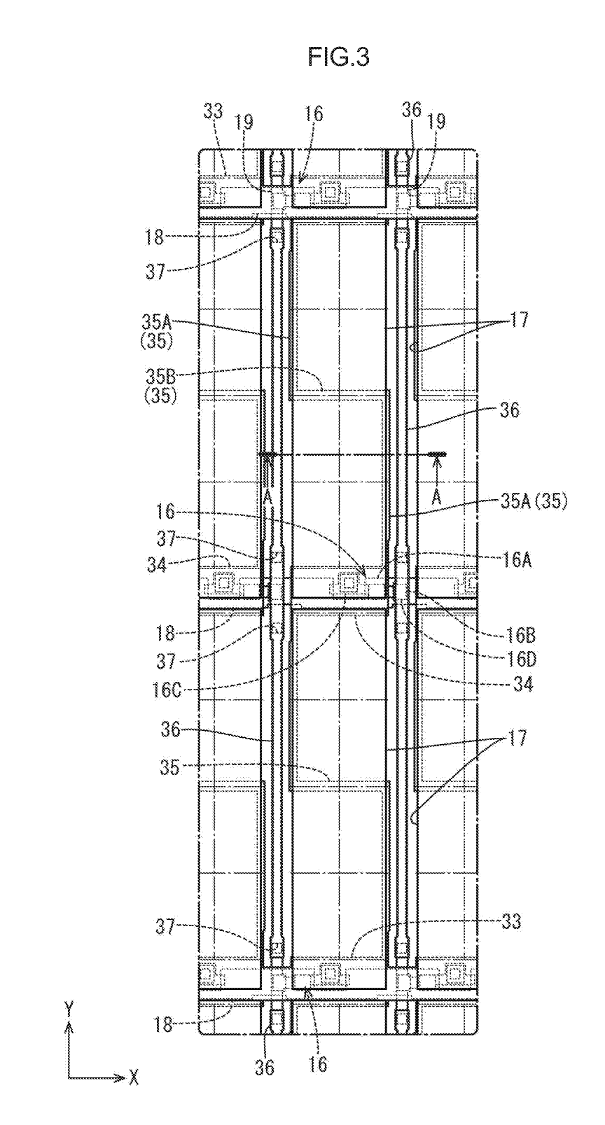

As illustrated in FIG. 3, in the display area AA of the array substrate 11B, TFTs (thin film transistors) 16, which are switching components, and pixel electrodes 17 are disposed in a matrix (columns and rows). Gate lines (scanning lines) 18 and source lines (signal lines, data lines) 19 are routed in a matrix to surround each pair of the TFT 16 and the electrode 17. The gate lines 18 extend substantially straight along the X-axis direction and are included in a relatively lower layer and the source lines 19 extend substantially straight along the Y-axis direction and are included in a relatively upper layer. The TFT 16 includes a gate electrode 16A connected to the gate line 18, a source electrode 16B connected to the source line 19, a drain electrode 16C connected to the pixel electrode 17, and a channel section 16D connected to the source electrode 16B and the drain electrode 16C. The TFT 16 is driven based on the scanning signal supplied through the gate line 18. Then, the potential relating the image signal that is supplied to the source line 19 is supplied to the drain electrode 16C through the channel section 16D such that the pixel electrode 17 is charged at the potential relating the image signal. The TFT 16 is off-centered on the pixel electrode 17 with respect to the X-axis direction as illustrated in FIG. 3. The pixel electrodes 17 each including the TFT 16 in a left side section and the pixel electrodes 17 each including the TFT 16 in a right side section are arranged alternately and repeatedly in the Y-axis direction and are arranged in a zig-zag way. A detailed structure of the TFT 16 be described later. The pixel electrode 17 is arranged in a substantially vertically-elongated quadrangular area that is surrounded by the gate lines 18 and the source lines 19. The pixel electrode 17 is sandwiched by a pair of gate lines 18 with respect to the Y-axis direction and sandwiched by a pair of source lines 19 with respect to the X-axis direction.

As illustrated in FIG. 4, the liquid crystal panel 11 includes a pair of substrates 11A and 11B, a liquid crystal layer (medium) 11C, and a pair of alignment films 11D and 11E. The liquid crystal layer 11C is interposed between the substrates 11A and 11B, and includes liquid crystal molecules (medium) that are vertically aligned. The alignment films 11D and 11E are vertical alignment films that align the liquid crystal molecules included in the liquid crystal layer 11C substantially vertically. The liquid crystal panel 11 according to this embodiment operates in the VA (Vertical Alignment) mode of a normally-black type. More particularly, the operation mode is a 4-domain reverse twisted nematic (4D-RTN) mode in which the alignment of the liquid crystal molecules is different in each of the domains that are included in the pixel electrode 17. In this embodiment, as illustrated in FIG. 3, one pixel electrode 17 is divided into eight domains and includes two domains arranged in the X-axis direction and four domains arranged in the Y-axis direction. In FIG. 3, border lines between the eight domains are illustrated with dashed lines. Specifically, the alignment films 11D and 11E are photo-alignment films surfaces of which are subjected to a photo-alignment treatment to provide alignment restriction force to the liquid crystal molecules. An appropriate photo-alignment treatment is performed to the respective domains. For the alignment film 11D on the CF substrate 11A side, the four domains that are arranged in the Y-axis direction are irradiated with the alignment treatment light rays (polarizing ultraviolet rays) along the X-axis direction during the producing process. The irradiation direction is opposite from each other by 180 degrees between the domains that are adjacent to each other in the Y-axis direction. For the alignment film 11E on the array substrate 11B side, the two domains that are arranged in the X-axis direction are irradiated with the alignment treatment light rays along the Y-axis direction during the producing process. The irradiation direction is opposite from each other by 180 degrees between the domains that are adjacent to each other in the X-axis direction. The liquid crystal molecules included in each domain are aligned in different directions by the pair of alignment films 11D and 11E that are subjected to the photo-alignment treatment as described above such that even viewing angle characteristic is achieved and display quality is good. The technology described in WO 2006/132369 or WO 2010/079703 can be applied to the above described domain division structure.

As illustrated in FIG. 4, the CF substrate 11A at least includes a color filter 20 and a light blocking section 21 on an inner surface side of the display area AA. The color filter 20 includes blue (B), green, (G), and red (R) color portions. The color portions that exhibit different colors are arranged next to each other alternately and repeatedly along the gate lines 18 (the X-axis direction) and extend along the source lines 19 (the Y-axis direction). Thus, the color portions are arranged in stripes as a whole. The color filter 20 overlaps each of the pixel electrodes 17 on the array substrate 11B side in a plan view. Each of pixels of three colors included in the liquid crystal panel 11 includes a set of three color portions, that is, R (red), G (green) and B (blue) color portions and three pixel electrodes 17 opposite to the color portions. The display pixel includes a blue pixel, a green pixel, and a red pixel that are adjacent to each other in the X-axis direction to exert color display with certain gradation. The pixels are arranged in the X-axis direction at intervals of about 70 μm (specifically, 67 μm) and are arranged in the Y-axis direction at intervals of about 200 μm (specifically, 201 μm). An overcoat film (a flattening film) 22 is disposed on the inner surface (an upper layer side) of the color filter 20 and a counter electrode 23 and the alignment film 11D are further disposed on the inner surface side of the color filter sequentially. The counter electrode 23 is a transparent electrode film that is disposed in a solid pattern over at least the display area AA and is opposite all of the pixel electrodes 17 while having the liquid crystal layer 11C therebetween. The counter electrode 23 is supplied with a reference potential such that potential difference is caused between the counter electrode 23 and the pixel electrode 17 that is charged by the TFT 16. According to such potential difference, the alignment state of the liquid crystal molecules of the liquid crystal layer 11C is altered to perform display with certain gradation for every pixel.

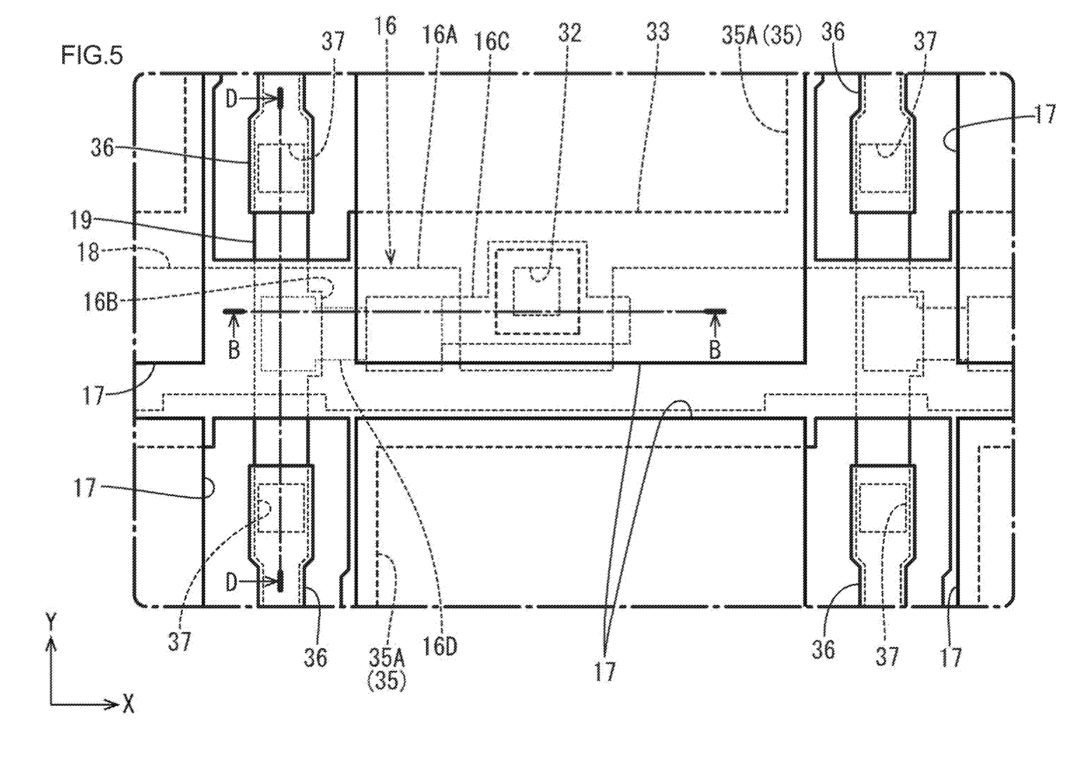

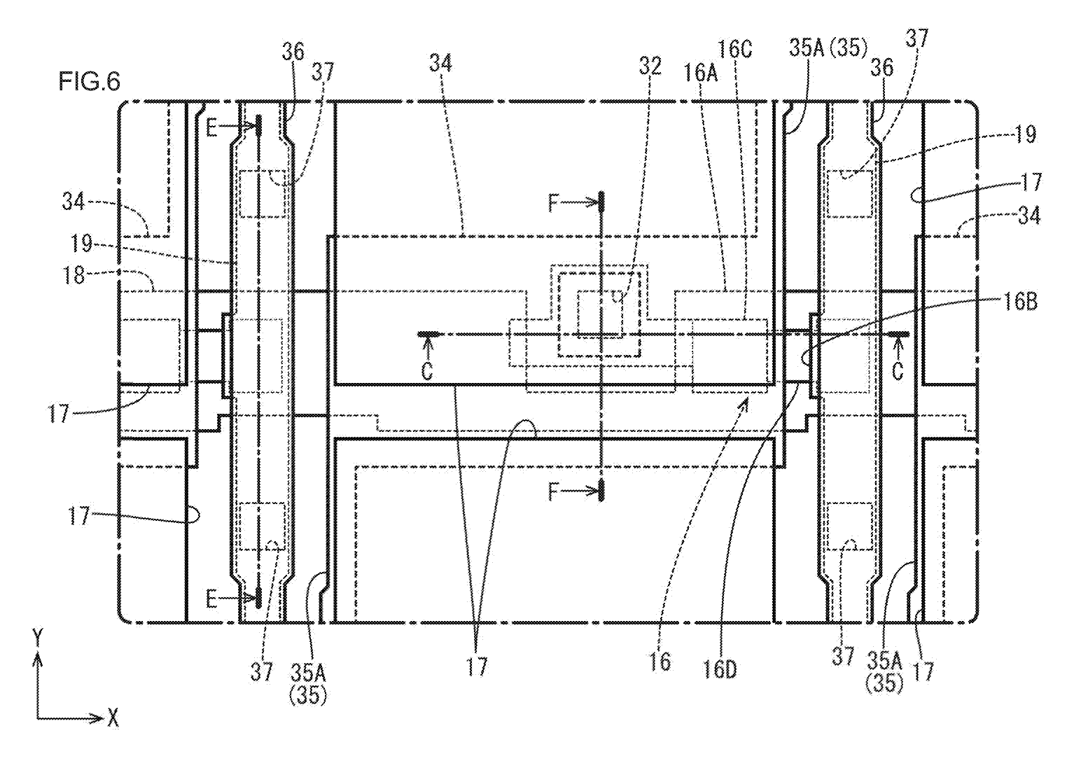

Configurations of the TFT 16 and the pixel electrode 17 will be described in detail. As illustrated in FIG. 3, the TFT 16 has a laterally elongated rectangular shape as a whole and extends in the X-axis direction. The TFT 16 is arranged on a lower side in FIG. 3 and next to the pixel electrode 11 that is to be connected to with respect to the Y-axis direction. As illustrated in FIGS. 5 and 6, the TFT 16 includes a gate electrode 16A that is a part of the gate line 18 (near an intersection of the gate line 18 and the source line 19). The gate electrode 16A has a laterally elongated rectangular shape extending in the X-axis direction and drives the TFT 16 according to the scanning signal supplied to the gate line 18. Accordingly, a current flowing between the source electrode 16B and the drain electrode 16C is controlled. The TFT 16 includes a source electrode 16B that is a part of the source line 19 (near an intersection of the gate line 18 and the source line 19). The source electrode 16B is disposed on one end portion of the TFT 16 with respect to the X-axis direction and the gate electrode 16A overlaps a substantially entire area of the source electrode 16B. The source electrode 16B is connected to the channel section 16D. The TFT 16 includes a drain electrode 16C on another end portion thereof with respect to the X-axis direction and the drain electrode 16C is spaced from the source electrode 16B. The drain electrode 16C extends in the X-axis direction. One end portion of the drain electrode 16C is opposite the source electrode 16B and overlaps the gate electrode 16A and is connected to the channel section 16D. Another end portion of the drain electrode 16C is connected to the pixel electrode 17. The pixel electrode 17 overlaps a substantially entire area of the drain electrode 16C and overlaps most of the section of the gate line 18 that is between a pair of source lines 19. The gate line 18 has a section overlapping a pixel contact hole 32 and a cutout is formed in the section. An entire area of the channel section 16D overlaps the gate electrode 16A and the channel section 16D extends in the X-axis direction and is connected to the source electrode 16B at one end portion thereof and is connected to the drain electrode 16C at another end portion thereof.

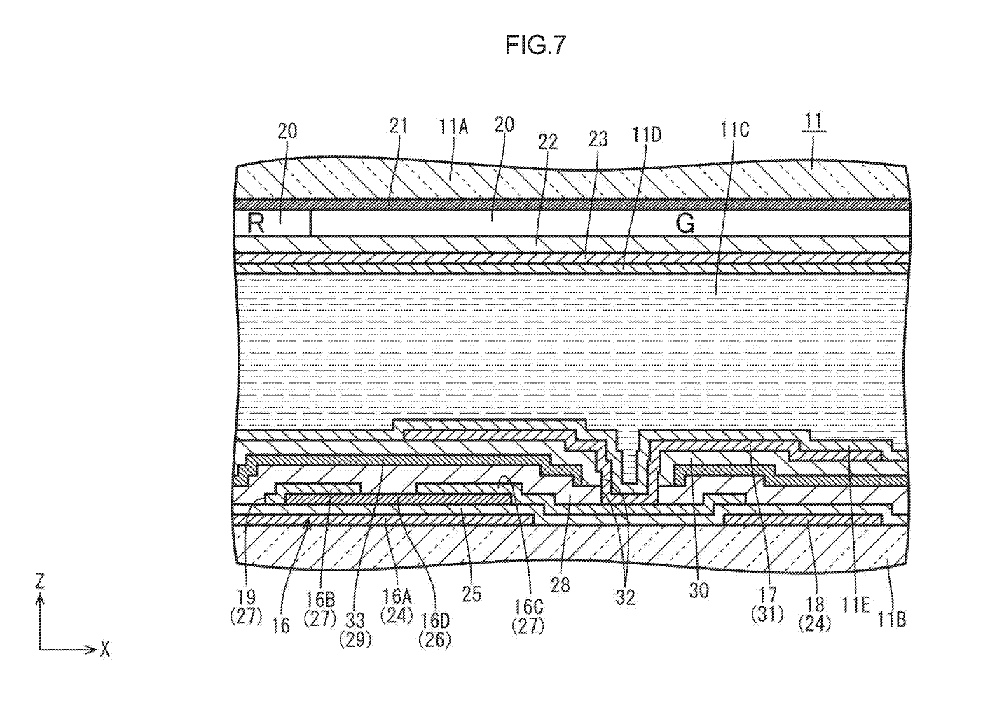

As illustrated in. FIG. 7, on the inner surface side of the array substrate 11B, the following films are formed in the following sequence from the lowest layer (the grass substrate). The films include a first metal film 24, a gate insulator 25, a semiconductor film 26, a second metal film 27, a first interlayer insulator 28, a third metal film 29, a second interlayer insulator (an insulator) 30, a transparent electrode film 31, and the alignment film 11E. Each of the first metal film 24, the second metal film 27, and the third metal film 29 is a single layer film made of one metal material selected from copper, aluminum, and others or a multilayer film made of different kinds of metal materials, or an alloy. Accordingly, the first metal film 24, the second metal film 27, and the third metal film 29 have conductivity and a light blocking property. The first metal film 24 forms the gate lines 18 and the gate electrodes 16A of the TFTs 16. The second metal film 27 forms the source lines 19, the source electrodes 16B and the drain electrodes 16C of the TFTs 16, and the auxiliary capacitor trunk lines 15. The third metal film 29 forms auxiliary capacitor lines 33, which will be described later. Each of the gate insulator 25, the first interlayer insulator 28, and the second interlayer insulator 30 is made of inorganic material such as silicon nitride (SiNₓ) and silicon oxide (SiO₂). The gate insulator 25 establishes insulation between the first metal film 24 included in the lower layer and the semiconductor film 26 and the second metal film 27 included in the upper layer. The first interlayer insulator 28 establishes insulation between the semiconductor film 26 and the second metal film 27 included in the lower layer and the third metal film 29 included in the upper layer. The second interlayer insulator 30 establishes insulation between the third metal film 29 included in the lower layer and the transparent electrode film 31 included in the upper layer. Each of the first interlayer insulator 28 and the second interlayer insulator 30 has the pixel contact hole 32 in the section thereof overlapping the pixel electrode 17 and the drain electrode 16C for connecting the pixel electrode 17 and the drain electrode 16C. The semiconductor film 26 is a thin film of an oxide semiconductor and forms the channel section 16D of the TFT 16. The transparent electrode film 31 is formed of transparent electrode material such as indium tin oxide (ITO) or indium zinc oxide (IZO) and forms the pixel electrode 17.

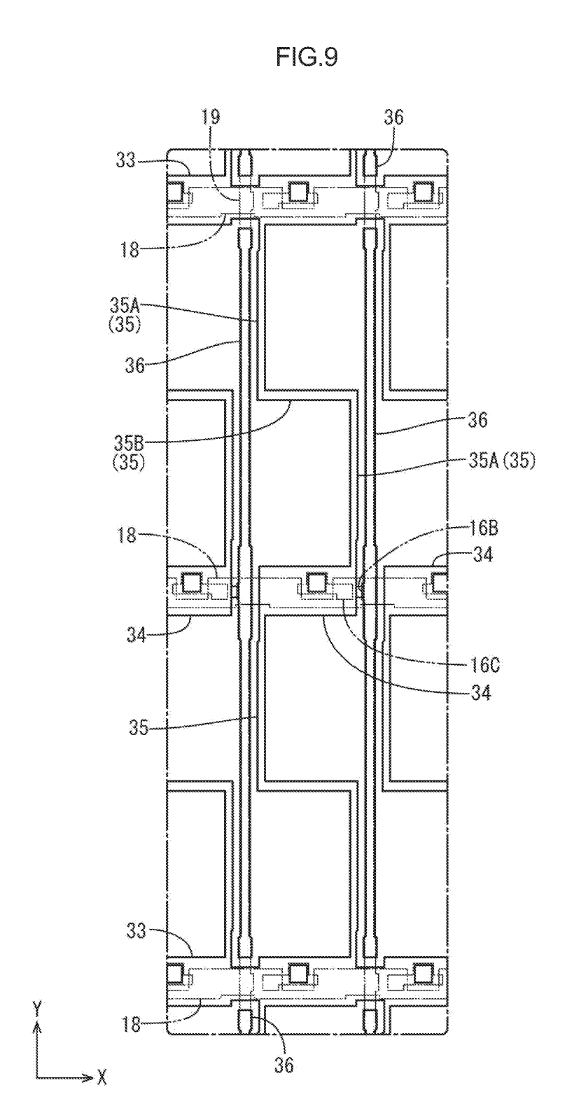

As illustrated in FIGS. 3 and 9, the array substrate 11B of this embodiment includes the auxiliary capacitor lines (a first auxiliary capacitor) 33 and auxiliary capacitor electrodes (a second auxiliary capacitor) 34 that are overlapped with the pixel electrodes 17 while having the second interlayer insulator 30 therebetween. Electrostatic capacitance (auxiliary capacitance) is created between the pixel electrode 17 and each of the auxiliary capacitor line 33 and the auxiliary capacitor electrode 34 to keep the potential held by the pixel electrode 17. The auxiliary capacitor line 33 extends in the X-axis direction and crosses the source line 19. The auxiliary capacitor line 33 crosses at least the pixel electrode 17 and the pair of source lines 19 sandwiching the pixel electrode 17 to receive the supply of the reference potential (a potential) from the auxiliary capacitor trunk line 15, which is a signal supply source. The auxiliary capacitor line 33 overlaps the pixel electrode 17 a part of which crosses the auxiliary capacitor line 33 while having the second interlayer insulator 30 therebetween. The auxiliary capacitor line 33 overlaps the source lines 19 in a plan view while having the first interlayer insulator 28 therebetween. The auxiliary capacitor electrode 34 is spaced away from the auxiliary capacitor line 33 in the Y-axis direction (the extending direction of the source line 19). The auxiliary capacitor electrode 34 overlaps the pixel electrode 17 in a plan view while having the second interlayer insulator 30 therebetween. However, the auxiliary capacitor electrode 34 does not overlap the pair of source lines 19 that sandwiches the pixel electrode 17 therebeteween. An auxiliary capacitor connecting section 35 that connects the auxiliary capacitor line 33 and the auxiliary capacitor electrode 34 is disposed on the array substrate 11B. The auxiliary capacitor electrode 34 is supplied with the reference potential from the auxiliary capacitor line 33 through the auxiliary capacitor connecting section 35. According to such a configuration, an electrostatic capacitance is created between each of the auxiliary capacitor line 33 and the auxiliary capacitor electrode 34 that are connected to each other by the auxiliary capacitor connecting section 35 and the pixel electrode 17 overlapping corresponding one of the auxiliary capacitor line 33 and the auxiliary capacitor electrode 34 while having the second interlayer insulator 30 therebetween. Accordingly, the potential of the pixel electrode 17 that is charged by the TFT 16 can be maintained. The auxiliary capacitor electrode 34 does not overlap the pair of source lines 19 and the parasitic capacitance is less likely to be caused between the source line 19 and the auxiliary capacitor electrode 34 compared to a configuration including the auxiliary capacitor electrode crossing the pair of source lines 19. Accordingly, blunting is less likely to be caused in the image signal transferred through the source line 19 and therefore, the configuration of this embodiment is preferable for achieving increase in size and enhancement of resolution.

As illustrated in FIG. 2, the auxiliary capacitor line 33 extends parallel to the gate line 18 and over an entire area of the display area AA. Two end portions of the auxiliary capacitor line 33 are connected to the auxiliary capacitor trunk lines 15, respectively, which are the signal supply source, in the non-display area NAA. Accordingly, the auxiliary capacitor line 33 is supplied with a common potential from the auxiliary capacitor trunk line 15 that is connected to the two end portions of the auxiliary capacitor line 33. The auxiliary capacitor lines 33 are arranged in the Y-axis direction at intervals and the auxiliary capacitor lines 33 that are adjacent to each other in the Y-axis direction are connected to each other through the auxiliary capacitor electrode 34 and the auxiliary capacitor connecting section 35 that are disposed between the adjacent auxiliary capacitor lines 33. Namely, two auxiliary capacitor lines 33 that are adjacent to each other in the Y-axis direction are connected to each other through one auxiliary capacitor electrode 34 and two auxiliary capacitor connecting sections 35 that are disposed between the two auxiliary capacitor lines 33 that are adjacent to each other in the Y-axis direction. Such a configuration is preferable to obtain an even potential distribution of the auxiliary capacitor line 33, the auxiliary capacitor electrode 34, and the auxiliary capacitor connecting section 35 in the display area AA.

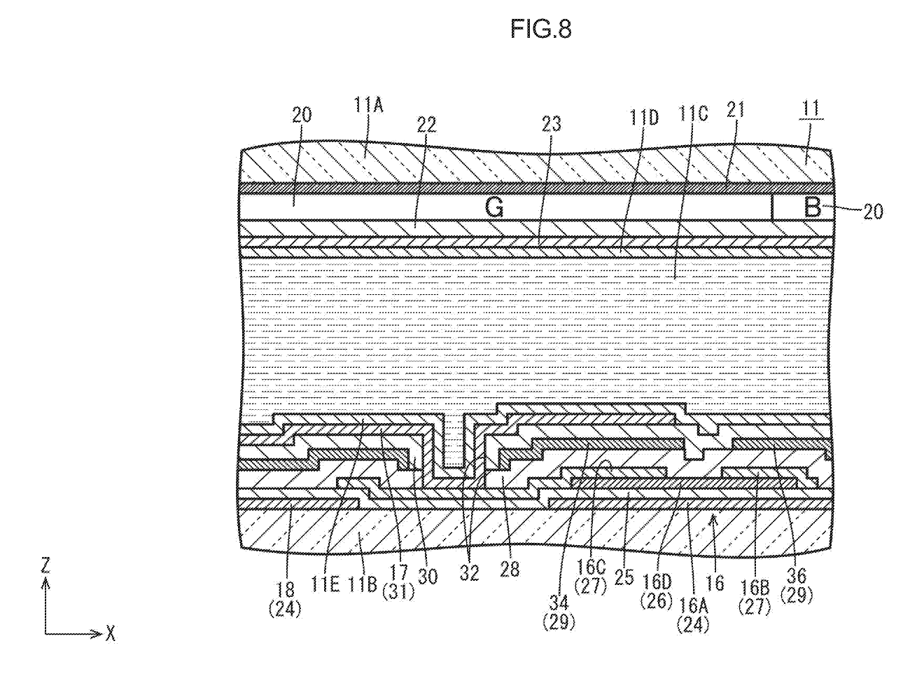

As illustrated in FIGS. 7 and 8, the auxiliary capacitor line 33 and the auxiliary capacitor electrode 34 are made from the third metal film 29. Namely, the auxiliary capacitor line 33 and the auxiliary capacitor electrode 34 are included in the same layer and included in a layer different from the gate line 18 that is made from the first metal film 24. According to such a configuration, the arrangement of the auxiliary capacitor line 33 and the auxiliary capacitor electrode 34 with respect to the gate lines 16 can be freely designed. A part of each of the auxiliary capacitor line 33 and the auxiliary capacitor electrode 34 overlaps the gate line 18 in a plan view. According to such a configuration, a light blocking area of the pixel electrode 17 where the light is blocked by the auxiliary capacitor line 33 and the auxiliary capacitor electrode 34 is reduced compared to a configuration that an auxiliary capacitor line and an auxiliary capacitor electrode do not overlap the gate line and overlaps the pixel electrode 17. Therefore, the configuration of this embodiment is preferable for improving an aperture ratio of the pixels. At least the gate insulator 25 and the first interlayer insulator 28 are present between the gate lines 18 and each of the auxiliary capacitor line 33 and the auxiliary capacitor electrode 34 to establish insulation therebetween. As illustrated in FIGS. 3 and 9, the auxiliary capacitor lines 33 and the auxiliary capacitor electrodes 34 are arranged in the Y-axis direction at intervals. Specifically, the auxiliary capacitor lines 33 and the auxiliary capacitor electrodes 34 are arranged in the Y-axis direction alternately and the interval between the auxiliary capacitor line 33 and the auxiliary capacitor electrode 34 is substantially same as a long-side dimension of the pixel electrode 17. Therefore, the auxiliary capacitor lines 33 overlap the odd-numbered or the even-numbered gate lines 18 front an edge with respect to the Y-axis direction and the auxiliary capacitor electrodes 34 overlap the even-numbered or the odd-numbered gate lines 18 from the edge in a plan view. As illustrated in FIGS. 7, 8 and 12, the auxiliary capacitor lines 33 and the auxiliary capacitor electrodes 34 have holes in portions thereof overlapping the pixel contact holes 32.

Furthermore, as illustrated in FIG. 4, the auxiliary capacitor connecting sections 35 that are connected to the auxiliary capacitor lines 33 and the auxiliary capacitor electrodes 34 are formed from the third metal film 29. Namely, the auxiliary capacitor connecting sections 35 are included in the same layer as the auxiliary capacitor lines 33 and the auxiliary capacitor electrodes 34. If the auxiliary capacitor connecting sections are formed from the second metal film 27 that is included in a different layer from the auxiliary capacitor lines 33 and the auxiliary capacitor electrodes 34, a contact hole is necessary to be formed in the first interlayer insulator 28 that is present between the auxiliary capacitor connecting section and each of the auxiliary capacitor lines 33 and the auxiliary capacitor electrodes 34 for connecting the auxiliary capacitor lines 33 and the auxiliary capacitor electrodes 34 to the auxiliary capacitor connecting section. However, in the present embodiment, the auxiliary capacitor connecting sections 35 are connected to the auxiliary capacitor lines 33 and the auxiliary capacitor electrodes 34 without forming the contact holes.

As illustrated is FIG. 9, the auxiliary capacitor connecting section 35 is arranged such that an entire plan view shape is point symmetric. Specifically, each of the auxiliary capacitor connecting sections 35 includes a pair of first connecting sections 35A and a second connecting section 35B that connects the pair of first connecting sections 35A. The two first connecting sections 35A are continuous from the auxiliary capacitor line 33 and the auxiliary capacitor electrode 34, respectively. The pair of first connecting sections 35A extend parallel to the source lines 19 along the Y-axis direction and have an extending length that is about a half of the long-side dimension of the pixel electrode 17. The two first connecting sections 35A in a pair are connected to the auxiliary capacitor line 33 and the auxiliary capacitor electrode 34, respectively, at one ends thereof with respect to the extending direction and connected to the second connecting section 35B at another ends thereof. The two first connecting sections 35A in a pair are arranged next to the pair of source lines 19 sandwiching the pixel electrode 17 with respect to the X-axis direction. Specifically, as illustrated in FIGS. 5 and 6, a part of each of the two first connecting sections 35A overlaps each long-side section of the pixel electrode 17. Each of the two first connecting sections 35A has a section that does not overlap the pixel electrode 17 and the section is sandwiched between the pixel electrode 17 and the source line 19. The two first connecting sections 35A are spaced from the adjacent source lines 19 by a same distance (for example, 5 μm) such that a parasitic capacitance is reduced and short-circuit is less likely to be caused between the first connecting sections 35A and the adjacent source lines 19. In producing the array substrate 11B, if the alignment of the pixel electrode 17, which is made from the transparent electrode film 31, does not correspond to the pair of first connecting sections 35A, which are made from the third metal film 29, and shifted toward either side with respect to the X-axis direction (a direction crossing the extending direction of the source line 19), the overlapping area of the pair of first connecting sections 35A and the pixel electrode 17 is less likely to be varied. Accordingly, variation in the values of the electrostatic capacitance created between the auxiliary capacitor connecting section 35 and the pixel electrode 17 that may be caused by the misalignment is less likely to be caused.

As illustrated in FIG. 9, the second connecting section 35B extends parallel to the gate line 18 along the X-axis direction and has an extending length that is substantially same as a short-side dimension of the pixel electrode 17. The second connecting section 35B is connected to the other ends of the two first connecting sections 35A at two ends thereof with respect to the extending direction thereof. The second connecting section 35B is substantially in a middle section of the long side of the pixel electrode 17 with respect to the Y-axis direction. As illustrated in FIG. 3, the second connecting section 35B overlaps a border line of the domains included in the pixel electrode 17 in a plan view. At the border lines between the domains included in the pixel electrode 17, alignment of the liquid crystal molecules is likely to be disturbed and a display image is likely to have a dark line (a dark portion) with a low display gradation. Since the second connecting section 35B overlaps the dark line, the aperture ratio of the pixels is less likely to be lowered.

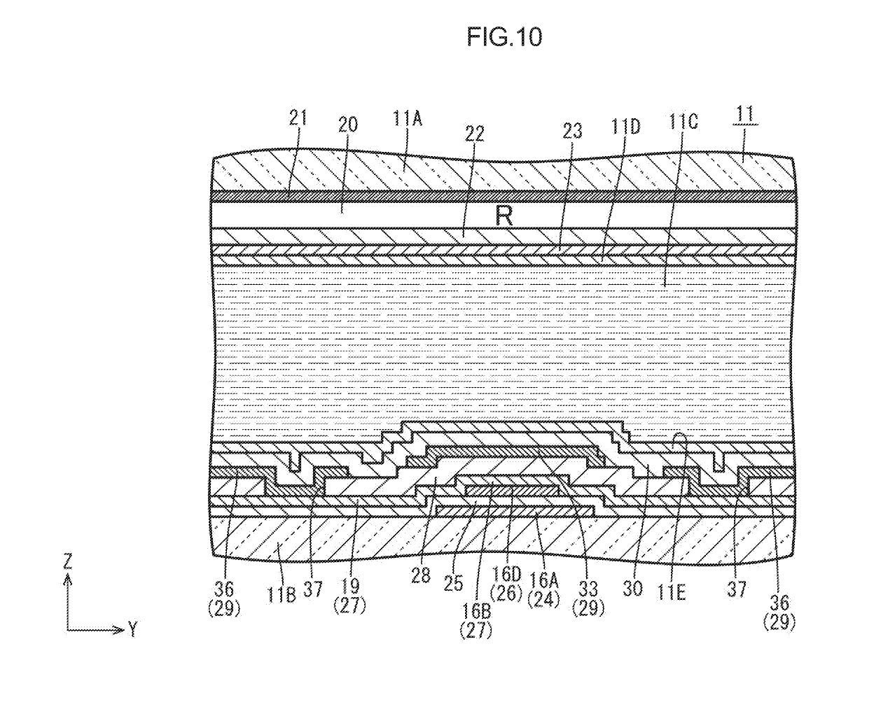

Furthermore, as illustrated in FIGS. 3 and 9, source overlapping lines (signal overlapping lines) 36 are disposed on the array substrate 11B. The source overlapping lines 36 extend parallel to the source lines 19 and most part of each source overlapping line 36 overlaps the source line 19. The source overlapping lines 36 are formed from the third metal film 29. Namely, the source overlapping lines 36 are included in the same layer as the auxiliary capacitor lines 33, the auxiliary capacitor electrodes 34, and the auxiliary capacitor connecting sections 35. The first interlayer insulator 28 is between the source overlapping lines 36 and the source lines 19 that are made from the second metal film 27 and overlap the respective source overlapping lines 36. As illustrated in FIG. 10, the first interlayer insulator 28 that is between the source overlapping lines 36 and the source lines 19 has contact holes 37 to connect them. According to such a configuration, the source lines 19 and the source overlapping lines 36 that are connected to each other through the contact holes 37 formed in the first interlayer insulator 28 configure a multiline. A line resistance of the source lines 19 is lowered and signal blunting is further less likely to be caused. The source overlapping lines 36 are formed from the third metal film 29 that is included in the array substrate 11B for providing the auxiliary capacitor lines 33 and the auxiliary capacitor electrodes 34, and a manufacturing cost is preferably reduced.

As illustrated in FIG. 9, the source overlapping line 36 extends between the two auxiliary capacitor lines 33 that are arranged in the Y-axis direction and two ends of the source overlapping line 36 with respect to the extending direction are adjacent to the two auxiliary capacitor lines 33 that are arranged in the Y-axis direction. According to such a configuration, the short-circuit is less likely to be caused between the source overlapping line 36 and the auxiliary capacitor line 33 while the source overlapping line 36 having a greatest length (a creepage distance, an occupied region). The source overlapping line 36 has the length that is about twice of the long-side dimension of the pixel electrode 17. The source overlapping line 36 extends in the Y-axis direction while having the auxiliary capacitor electrode 34 in a middle section thereof. If the auxiliary capacitor electrode overlaps the source line 19, the length of the source overlapping line is reduced by a width dimension of the auxiliary capacitor electrode and a distance between the source overlapping line and the auxiliary capacitor electrode for preventing the short circuit. Compared to such a configuration, the length of the source overlapping line 36 can be increased in this embodiment, and the line resistance of the source line 19 can be preferably lowered. The auxiliary capacitor electrode 24 that is included in the same layer as the source overlapping line 36 does not overlap the source line 19. Therefore, even if the source overlapping line 36 extends in the Y-axis direction while having the auxiliary capacitor electrode 34 at a middle section thereof, the short circuit is less likely to be caused between the source overlapping line 36 and the auxiliary capacitor electrode 34. The source overlapping line 36 has a center line that substantially matches a center line of the source line 19.

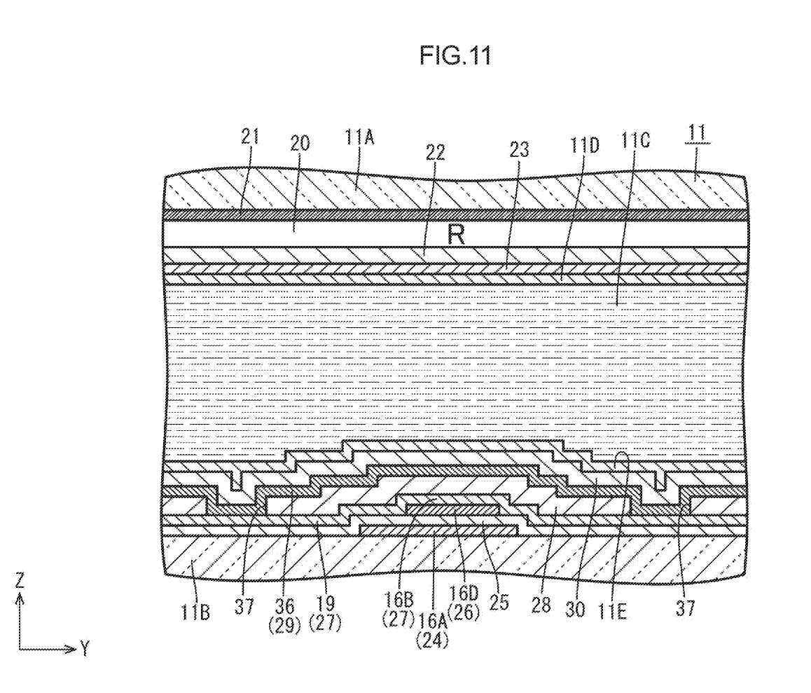

As illustrated in FIGS. 10 and 11, the first interlayer insulator 28 that is between the source overlapping line 36 and the source line 19 has the contact holes 37 at positions corresponding to the two end portions of the source overlapping line 36 with respect to the Y-axis direction and two positions so as to sandwich the auxiliary capacitor electrode 34 with respect to the Y-axis direction. Namely, one source overlapping line 36 is connected to the overlapping source line 19 at four sections through the four contact holes 37 that are spaced from each other in the Y-axis direction. The four contact holes 37 are adjacent to the gate lines 18 that overlap the auxiliary capacitor line 33 and the auxiliary capacitor electrode 34, respectively. According to such an arrangement, the source overlapping line 36 is connected to the source line 19 surely (redundancy is ensured) and degradation in display quality that may be caused by the contact holes 37 is less likely to be seen.

As described before, the array substrate (the substrate for a display device) 11B according to the present embodiment includes the pixel electrode 17, at least two source lines (signal lines) 19, the auxiliary capacitor line 33 that is a first auxiliary capacitor, the auxiliary capacitor electrode 34 that is a second auxiliary capacitor, and the auxiliary capacitor connecting section 35. The source lines 19 are disposed to sandwich the pixel electrode 17 and supply a signal to the pixel electrode 17. The auxiliary capacitor line 33 extends and crosses the pixel electrode 17 and the source lines 19. The auxiliary capacitor line 33 overlaps the source lines 19 while having the first interlayer insulator (an insulator) 28 therebetween and overlaps the pixel electrode 17 while having the second interlayer insulator (the insulator) 30 therebetween. The auxiliary capacitor electrode 34 is spaced from the auxiliary capacitor line 33 with respect to the extending direction of the source line 19 and overlaps the pixel electrode 17 while having the second interlayer insulator 30 therebetween. The auxiliary capacitor electrode 34 does net overlap at least one of the two source lines 19. The auxiliary capacitor connecting section 35 connects the auxiliary capacitor line 33 and the auxiliary capacitor electrode 34.

According to such a configuration, the pixel electrode 17 is supplied with the signal transferred through the source line 19 and charged at a predetermined potential. The auxiliary capacitor line 33 and the auxiliary capacitor electrode 34 connected by the auxiliary capacitor connecting section 35 create an electrostatic capacitance with the pixel electrode 17 overlapping each of the auxiliary capacitor line 33 and the auxiliary capacitor electrode 34 via the second interlayer insulator 30 such that the potential of the charged pixel electrode 17 can be maintained. The auxiliary capacitor line 33 extends and crosses the source lines 19 that sandwich the pixel electrode 17 so as to be supplied with a potential from the auxiliary capacitor trunk line 15, which is the signal supply source. The auxiliary capacitor electrode 34 is supplied with a potential from the auxiliary capacitor line 33 through the auxiliary capacitor connecting section 35. The auxiliary capacitor electrode 34 does not overlap at least one of the two source lines 19. According to such a configuration, the parasitic capacitance that may be created between the source line 19 and the auxiliary capacitor electrode 34 can be reduced compared to a configuration that the auxiliary capacitor electrode crosses the two source lines 19. As a result, blunting is less likely to be caused in the signal transferred through the source line 19 and the present embodiment is preferable for increasing a size and enhancing resolution.

The substrate further includes the gate line (a scanning line) 18 that extends and crosses the source lines 19. The auxiliary capacitor line 33 and the auxiliary capacitor electrode 34 are included in the same layer and are included in a different layer from the gate line 18. According to such a configuration, the auxiliary capacitor line 33 and the auxiliary capacitor electrode 34 can be arranged mere freely with respect to the gate line 18 compared to a configuration including the auxiliary capacitor line and the auxiliary capacitor electrode in the same layer as the gate line 18.

The auxiliary capacitor line 33 is disposed such that a part thereof overlaps the gate line 18. According to such a configuration, the aperture ratio is preferably increased compared to a configuration that the auxiliary capacitor line does not overlap the gate line 18.

The substrate includes the display area AA including the pixel electrodes 17 arranged in a matrix. The pixel electrodes 17 are arranged in the extending directions of the source lines 19 and the gate lines 18. The auxiliary capacitor lines 33 are arranged in the extending direction of the source lines 19 at intervals in the display area AA. The auxiliary capacitor lines 33 extend parallel to the gate line 18 over an entire area of the display area AA. According to such a configuration, the auxiliary capacitor line 33 extending parallel to the gate line 18 over an entire area of the display area AA can be supplied with signals from the auxiliary capacitor trunk line 15, which is the single supply source, outside the display area AA.

The auxiliary capacitor lines 33 are connected to each other through the auxiliary capacitor electrode 34 and the auxiliary capacitor connecting section 35. Accordingly, an even potential contribution of the auxiliary capacitor lines 33, the auxiliary capacitor electrode 34, and the auxiliary capacitor connecting section 35 within the display area AA can be preferably obtained.

The auxiliary capacitor electrode 34 is disposed such that at least a part thereof overlaps the gate line 18. According to such a configuration, the aperture ratio is preferably increased compared to a configuration in which the auxiliary capacitor electrode does not overlap the gate line 18.

The auxiliary capacitor connecting section 35 is included in the same layer as the auxiliary capacitor line 33 and the auxiliary capacitor electrode 34. If the auxiliary capacitor connecting section is included in a different layer from the auxiliary capacitor line 33 and the auxiliary capacitor electrode 34, a contact hole is required to be formed in the insulator that is between the auxiliary capacitor connecting section 35 and each of the auxiliary capacitor line 33 and the auxiliary capacitor electrode 34 for the connection. According to the configuration of the present embodiment, the auxiliary capacitor connecting section 35 can be connected to the auxiliary capacitor line 33 and the auxiliary capacitor electrode 34 without forming such contact holes.

The substrate further includes a source overlapping line (a signal overlapping line) 36 included in the same layer as the auxiliary capacitor line 33 and the auxiliary capacitor electrode 34 and extending parallel to the source line 19 and a part of the source line overlapping line overlaps the source line 19. The first interlayer insulator 28 that is between the source line 19 and the source overlapping line 36 has the contact holes 37 through which the source line 19 and the source overlapping line 36 are connected. According to such a configuration, the source line 19 is connected to the source overlapping line 36 through the contact holes 37 formed in the first interlayer insulator 28. Therefore, the line resistance is decreased and signal blunting is less likely to be caused. The source overlapping line 36 is included in the same layer as the auxiliary capacitor line 33 and the auxiliary capacitor electrode 34 and the manufacturing cost can be preferably reduced.

The source overlapping line 36 extends in the extending direction of the source line 19 while having the auxiliary capacitor electrode 34 at a middle section thereof. According to such a configuration, the creepage distance of the source overlapping line 36 can be increased compared to a configuration including the auxiliary capacitor electrode overlapping The source line 19. Therefore, line resistance of the source line 19 can be preferably reduced. The auxiliary capacitor electrode 34 that is included in the same layer as the source overlapping line 36 does not overlap the source line 19. Therefore, even if the source overlapping line 36 extends in the extending direction of the source line 19 while having the auxiliary capacitor electrode 34 at a middle section thereof, short circuit is less likely to be caused between the source overlapping line 36 and the auxiliary capacitor electrode 34.

The gate lines 18 are arranged in the extending direction of the source line 19 at intervals. The auxiliary capacitor line 33 and the auxiliary capacitor electrode 34 are arranged such that at least a part of each of the auxiliary capacitor line 33 and the auxiliary capacitor electrode 34 overlaps the gate line 18. The first interlayer insulator 28 that is between the source overlapping line 36 and the source line 19 has the contact holes 37 at positions corresponding to the two end portions of the source overlapping line 36 with respect to the extending direction thereof and two positions so as to sandwich the auxiliary capacitor electrode 34 with respect to the extending direction thereof. The source overlapping line 36 is included in the same layer as the auxiliary capacitor line 33 that crosses the pair of source lines 19. Therefore, the arrangement range of the source overlapping line 36 with respect to the extending direction is not over the auxiliary capacitor line 33 in view of preventing the short circuit. To maximize the arrangement range of the source overlapping line 36 with respect to the extending direction, the source overlapping line 36 is preferably disposed such that an end portion thereof is adjacent to the auxiliary capacitor line 33. The first interlayer insulator 28 includes the contact holes 37 in the positions corresponding to the two ends of the source overlapping line 36 and two positions so as to sandwich the auxiliary capacitor electrode 34. According to such an arrangement, the contact holes 37 are adjacent to the gate lines 18 that overlap the auxiliary capacitor line 33 and the auxiliary capacitor electrode 34, respectively. Therefore, the source overlapping line 36 is connected to the source line 19 surely and degradation in display quality that may be caused by the contact holes 37 is less likely to be seen.

The second auxiliary capacitor includes the auxiliary capacitor electrode 34 that does not overlap the pair of source lines 19 sandwiching the pixel electrode 17. According to such a configuration, the auxiliary capacitor electrode 34 included in the second auxiliary capacitor overlaps single pixel electrode 17 and does not overlap the pair of source lines 19 sandwiching the pixel electrode 17. Therefore, according to the configuration of this embodiment, the parasitic capacitance that may be caused between the auxiliary capacitor electrode 34 and the source line 19 is reduced compared to a configuration that the auxiliary capacitor electrode 34 overlaps the source line 19.

The auxiliary capacitor connecting section 35 is arranged such that an entire plan view shape is point symmetric. According to such a configuration, compared to the configuration including the auxiliary capacitor connecting section having a plan view shape that is not point symmetric, variation in the values of the electrostatic capacitance created between the auxiliary capacitor connecting section 35 and the pixel electrode 17 that may be caused by the misalignment of the pixel electrode 17 and the auxiliary capacitor connecting section 35 in the direction crossing the extending direction of the source line 19 is less likely to be caused.

The liquid crystal panel (the display device) 11 of this embodiment includes the array substrate 11B and the CF substrate (the counter substrate) 11A that is disposed opposite the array substrate 11B. According to the liquid crystal panel 11 having such a configuration, blunting is less likely to be caused in the signals transferred through the source line 19 and good display quality can be obtained.

### Second Embodiment

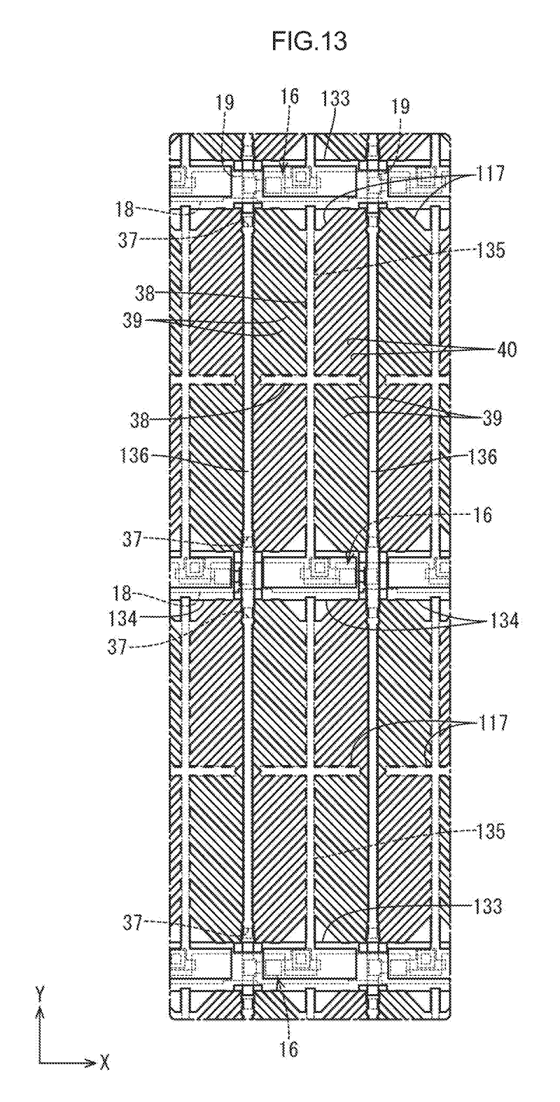

A second embodiment of the present technology will be described with reference to FIGS. 13 to 15. In the second embodiment, a display mode of the liquid crystal panel is altered from that of the first embodiment. Configurations, operations, and advantageous effects same as those of the first embodiment will not be described.

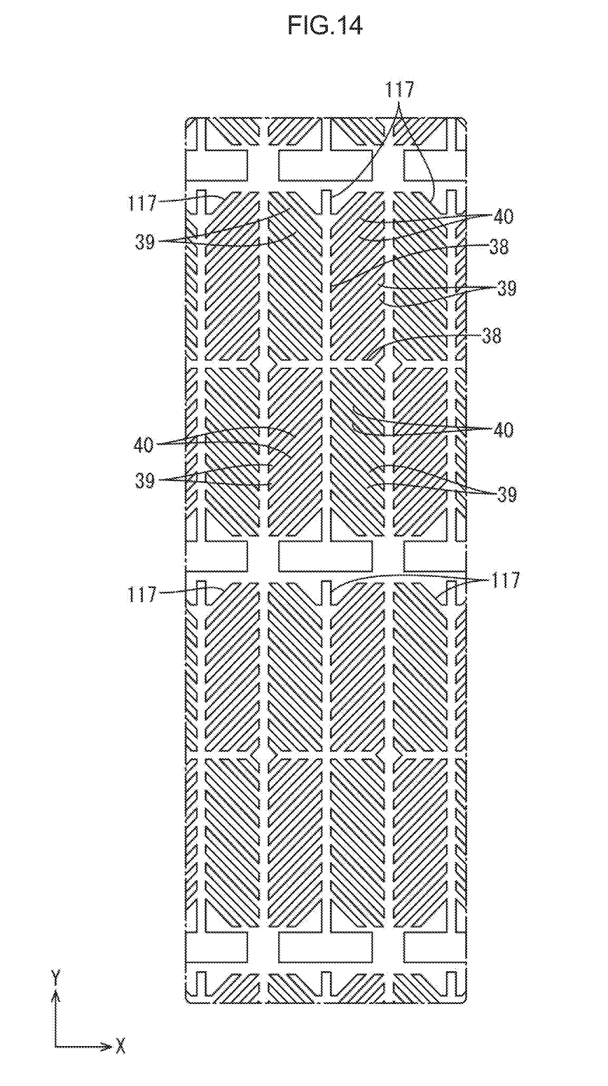

As illustrated in FIG. 13, a display mode of the liquid crystal panel according to this embodiment is a VA mode in which liquid crystal molecules included in the liquid crystal layer are aligned with using slits 40 included in pixel electrodes 117. Specifically, as illustrated in FIG. 14, the pixel electrode 117 includes a trunk electrode section 38 and branch electrode sections 39 that extend radially from the trunk electrode section 38. The pixel electrode 117 includes the slits 40 between the branch electrode sections 39 and has a fishbone shape as a whole. The trunk electrode section 38 has a cross plan view shape as a whole and includes a section extending in the X-axis direction and a section extending in the Y-axis direction. The branch electrode sections 39 extend from the trunk electrode section 38 obliquely with respect to the X-axis direction and the Y-axis direction. One ends of the respective branch electrode sections 39 are continuous to the trunk electrode section 38. The branch electrode sections 39 are arranged at equal intervals (a width dimension of the slit 40) in the extending direction of the trunk electrode section 38. The slit 40 between the adjacent branch electrode sections 39 has a thin elongated groove shape that is parallel to the branch electrode sections 39. The slits 40 are arranged at equal intervals in the extending direction of the trunk electrode section 38. The array substrate has recesses (sections having no electrode) in sections overlapping the slits 40. An electric field is created according to the shape of the recesses and the liquid crystal molecules included in the liquid crystal layer are aligned radially according to the shape of the recesses.

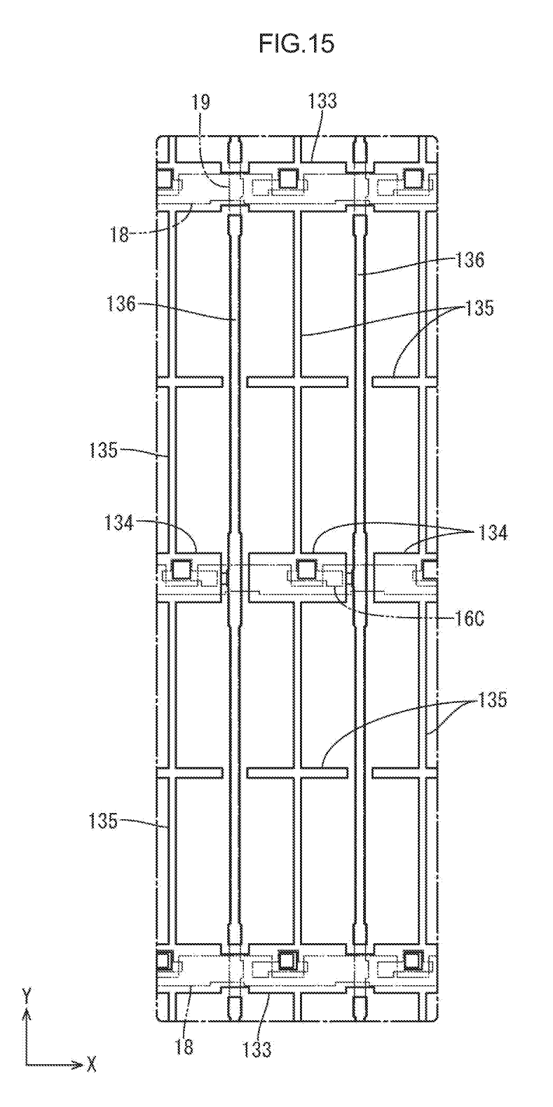

As illustrated in FIGS. 13 and 15, an auxiliary capacitor connecting section 135 selectively overlaps the trunk electrode section 38 of the pixel electrode 117. In sections of the pixel electrode 117 near the trunk electrode section 38, alignment of the liquid crystal molecules is likely to be disturbed and a display image is likely to have a dark line (a dark portion) with a low display gradation. The auxiliary capacitor connecting section 135 overlaps the dark line such that the aperture ratio of the pixels is less likely to be lowered. The auxiliary capacitor connecting section 135 includes a section extending in the Y-axis direction and having two ends that are connected to an auxiliary capacitor line 133 and an auxiliary capacitor electrode 134, respectively, and a section extending in the X-axis direction. The auxiliary capacitor connecting section 135 has a cross plan view shape as a whole similar to the shape of the trunk electrode section 38. The auxiliary capacitor connecting section 135 is disposed such that the section extending in the X-axis direction and the section extending in the Y-axis direction are on substantially middle sections of the pixel electrode 117 with respect to the Y-axis direction and the X-axis direction, respectively. The section of the auxiliary capacitor connecting section 135 extending in the Y-axis direction and formed from the third metal film is disposed farthest from a source overlapping line 136 that is parallel to the section and formed from the third metal film. Therefore, the short circuit between the auxiliary capacitor connecting section 135 and the source overlapping line 136 is less likely to be caused. The auxiliary capacitor connecting section 135 is disposed over substantially an entire area of the trunk electrode section 38. Therefore, electrostatic capacitance created between the auxiliary capacitor connecting section 135 and the pixel electrode 117 is increased.

### Third Embodiment

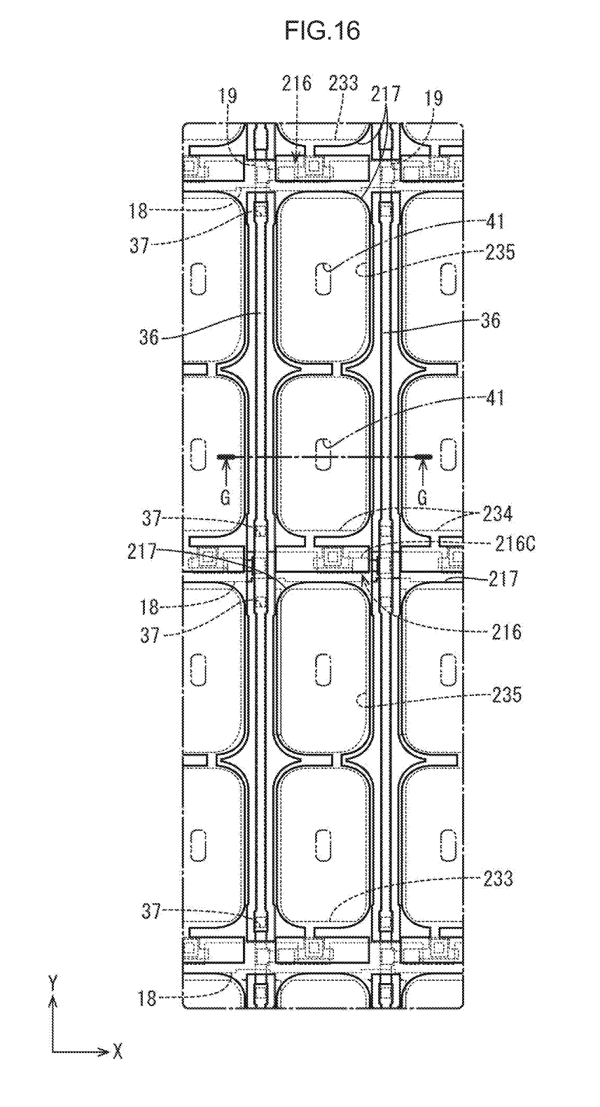

A third embodiment of the present technology will be described with reference to FIGS. 16 to 19. In the third embodiment, a display node of a liquid crystal panel 211 is altered from that of the first embodiment. Configurations, operations, and advantageous effects same as those of the first embodiment will not be described.

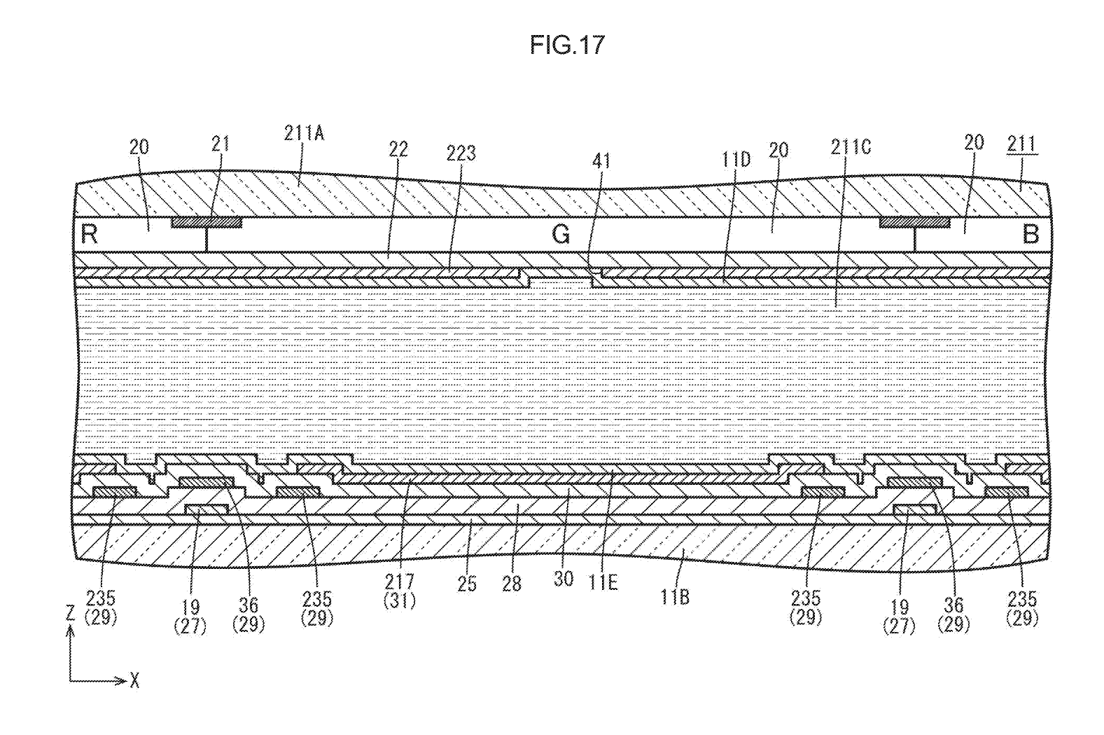

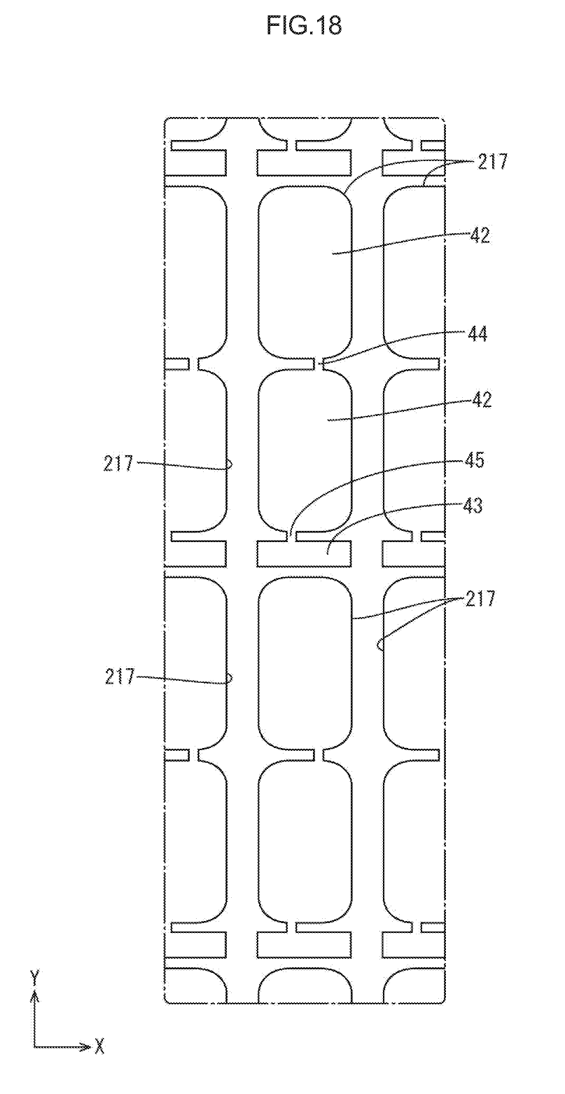

As illustrated in FIGS. 16 and 17, a display mode of the liquid crystal panel 211 according to this embodiment is a continuous pinwheel alignment (CPA) mode in which liquid crystal molecules included in a liquid crystal layer 211C are aligned with using holes (cutouts) 41 included in a counter electrode 223 of a CF substrate 211A. In FIG. 16, the holes Al are illustrated with two-dot chain lines. Specifically, the counter electrode 223 has two holes 41 in each section overlapping each pixel electrode 217. A recess is formed on a surface of the counter electrode 223 due to the hole 41. As illustrated in FIG. 18, the pixel electrode 217 that is opposite the counter electrode 223 includes two sub pixel electrodes 42, a contact section 43, a first connecting section 44, and a second connecting section 45. The contact section 43 is connected to a drain electrode 216C of a TFT 216. The first connecting section 44 connects the two sub pixel electrodes 42, and the second connecting section 45 connects one of the sub pixel electrodes 42 and the contact section 43. The sub pixel electrode 42 has a vertically elongated rectangular shape having round corners in a plan view. The contact section 43 overlaps the TFT 216 in a plan view and has a laterally elongated rectangular shape extending along the TFT 216. As illustrated in FIG. 16, two holes 41 are formed in every pixel electrode 217 and each of the holes 41 is at a center of each sub pixel electrode 42 in a plan view. Therefore, liquid crystal molecules included in the liquid crystal layer are aligned radially from the hole 41.

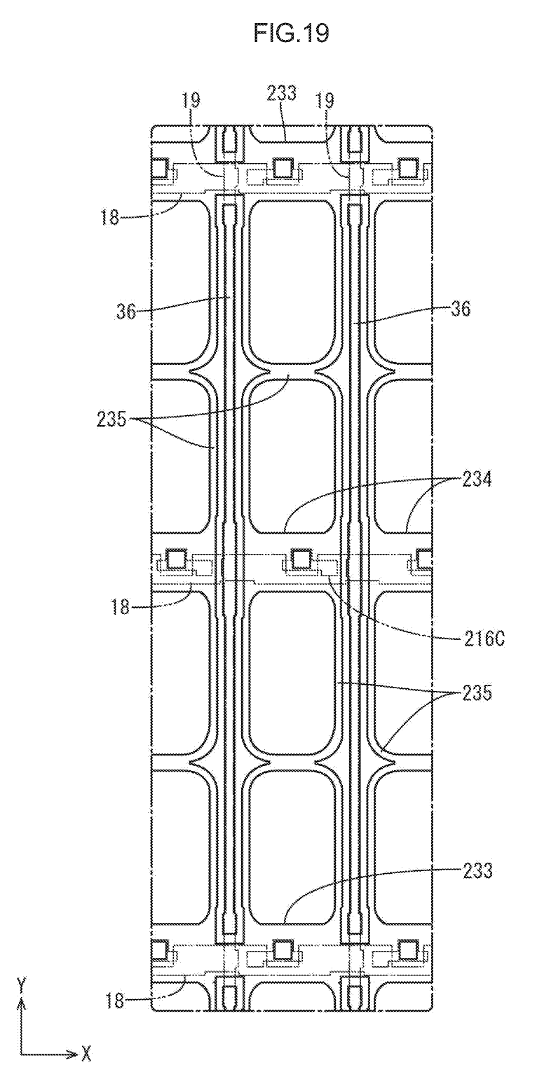

As illustrated in FIGS. 16 and 19, an auxiliary capacitor connecting section 235 extends along an outer edge portion of each sub pixel electrode 42 of the pixel electrode 217 and a part of the auxiliary capacitor connecting section 235 overlaps the edge portion of each sub pixel electrode 42. Specifically, the auxiliary capacitor connecting section 235 extends parallel to two long-side edge portions of each sub pixel electrode 42 and extends parallel to short-side edge portions of each sub pixel electrode 42 opposite from the short-side edge portions on the auxiliary capacitor line 233 side and the auxiliary capacitor electrode 234 side. Since the edge portion of each sub pixel electrode 42 of the pixel electrode 217 is farthest from the hole 41 in a plan view, the response of the liquid crystal molecules included in the liquid crystal layer 211C is slowest. Therefore, an afterimage is likely to be caused in displaying movie. The auxiliary capacitor connecting section 235 overlaps the edge portion of each sub pixel electrode 42 where the afterimage is likely to be caused. According to such an arrangement, the aperture ratio of the pixels is less likely to be lowered by the auxiliary capacitor connecting section 235.

### Fourth Embodiment

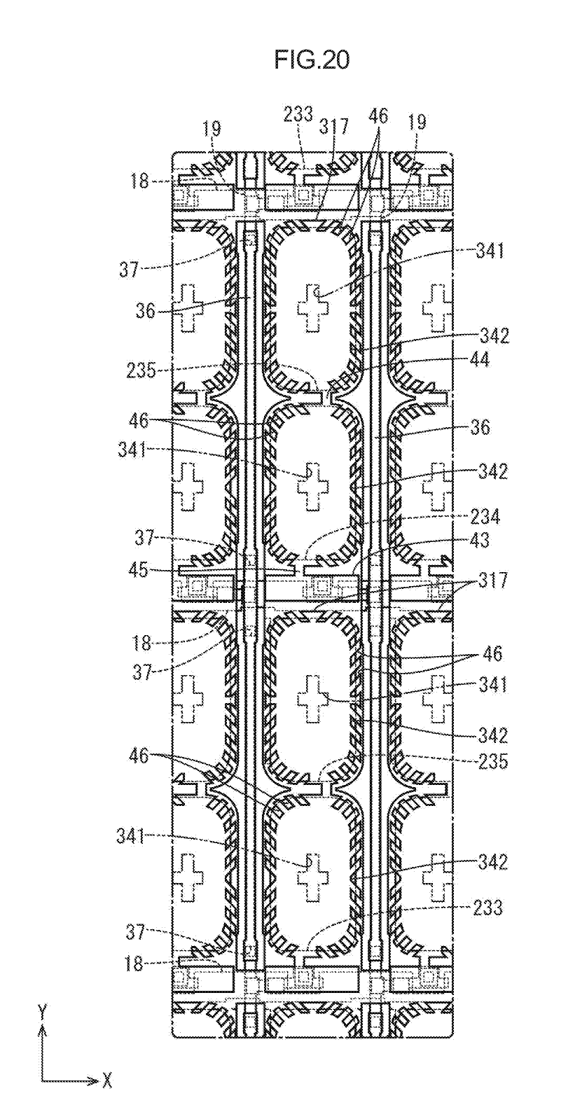

A fourth embodiment of the present technology will be described with reference to FIG. 20. In the fourth embodiment, configurations of a pixel electrode 317 and a hole 341 are different from those of the third embodiment. Configurations, operations, and advantageous effects same as those of the third embodiment will not be described.

As illustrated in FIG. 20, the pixel electrode 317 of this embodiment includes slits 46 on an edge portion of each sub pixel electrode 342. The slits 46 are arranged at intervals along the edge portion of each sub pixel electrode 342 and are arranged substantially evenly along an entire periphery of each sub pixel electrode 342. The hole 341 has a plan view cross shape. According to such a configuration, the response of the liquid crystal molecules included in the liquid crystal layer is faster than that of the third embodiment. An electrostatic capacitance created between the pixel electrode 317 and the auxiliary capacitor connecting section. 335 is smaller since the slits 46 are formed in the pixel electrode 317. Since the pixel electrode 217 has a larger area in the third embodiment compared to the fourth embodiment, the electrostatic capacitance created between the pixel electrode 217 and the auxiliary capacitor connecting section 235 is increased. (see FIG. 16)

### Fifth Embodiment

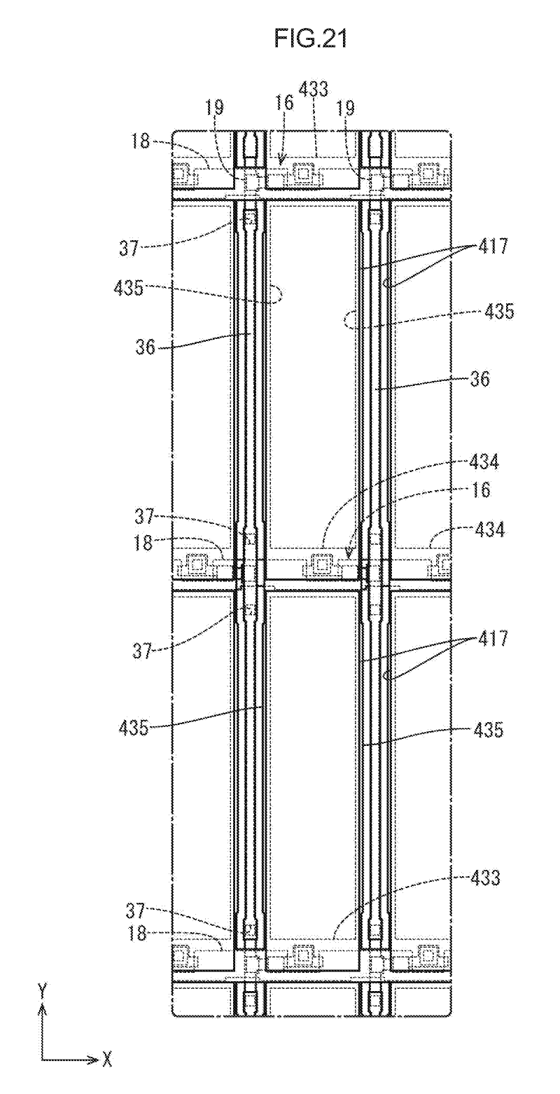

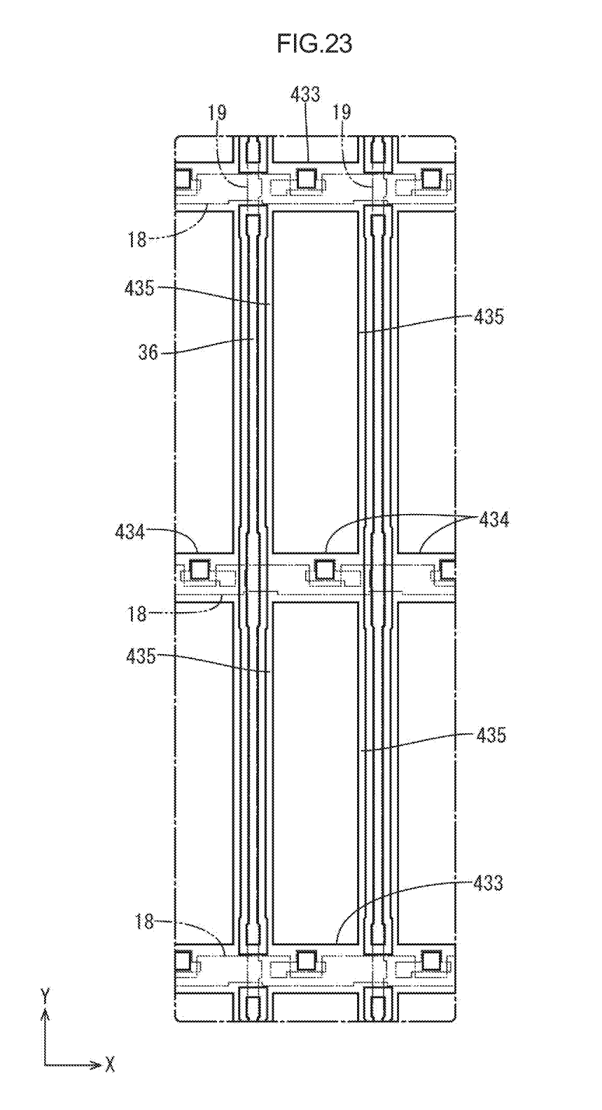

A fifth embodiment of the present technology will be described with reference to FIGS. 21 to 23. In the fifth embodiment, a display mode of a liquid crystal panel is altered from that of the first embodiment. Configurations, operations, and advantageous effects same as those of the first embodiment will not be described.

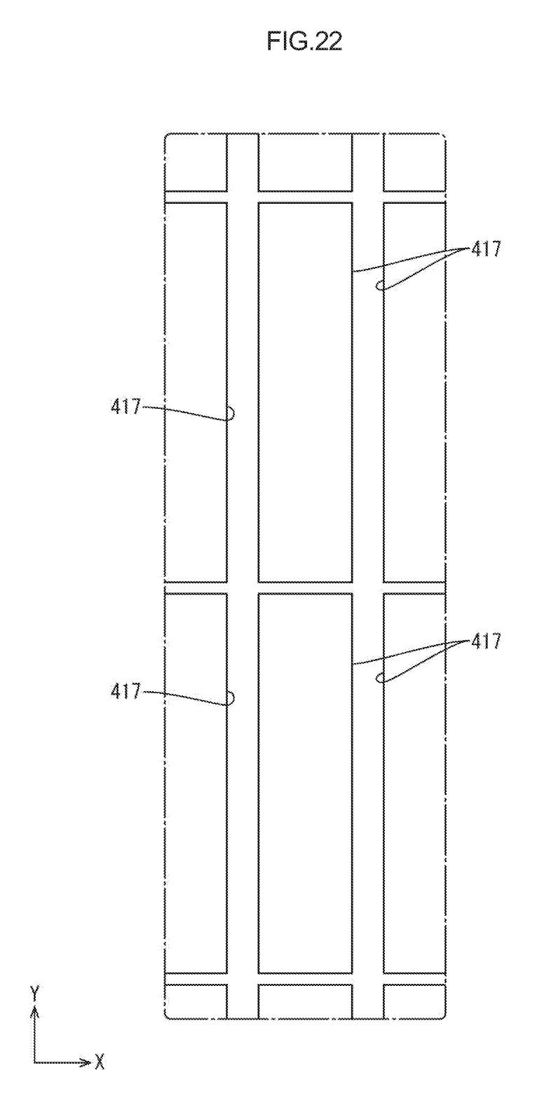

As illustrated in. FIG. 21, the liquid crystal panel according to this embodiment is operated in a twisted nematic (TN) mode. Specifically as illustrated in FIG. 22, a pixel electrode 417 has a vertically elongated rectangular plan view shape. An auxiliary capacitor connecting section 435 extends parallel to two long-side edge portions of the pixel electrode 417 and linearly in the Y-axis direction. A part of the auxiliary capacitor connecting section 435 overlaps each of the two long-side edge portions of the pixel electrode 417. Since the auxiliary capacitor connecting section 435 configure a multiline, the redundancy is ensured and high connection reliability of the auxiliary capacitor lines 433 and the auxiliary capacitor electrodes 434 is maintained and the resistance is lowered.

### Sixth Embodiment

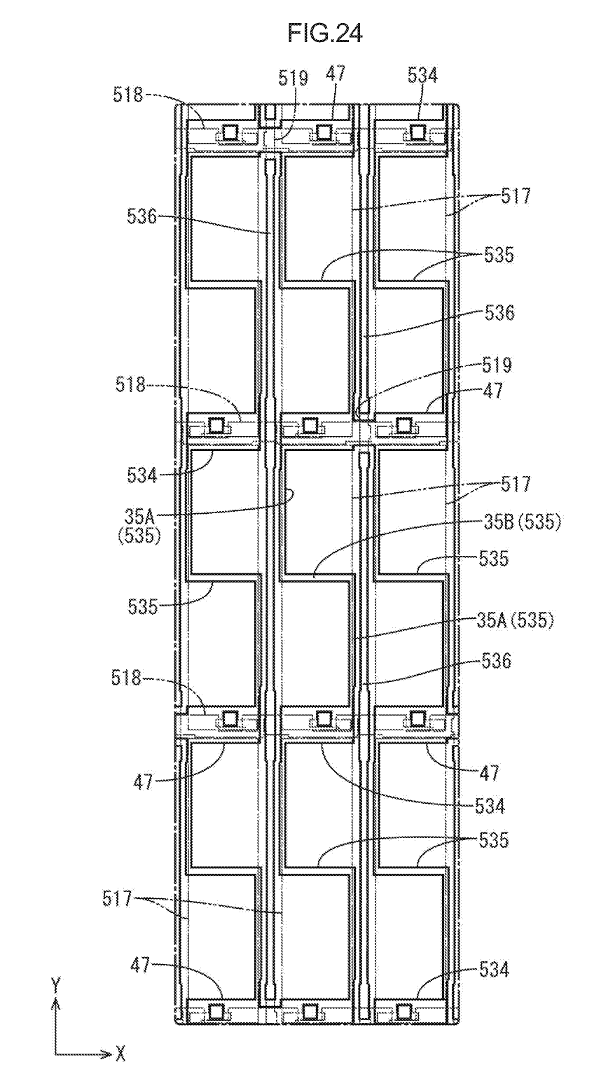

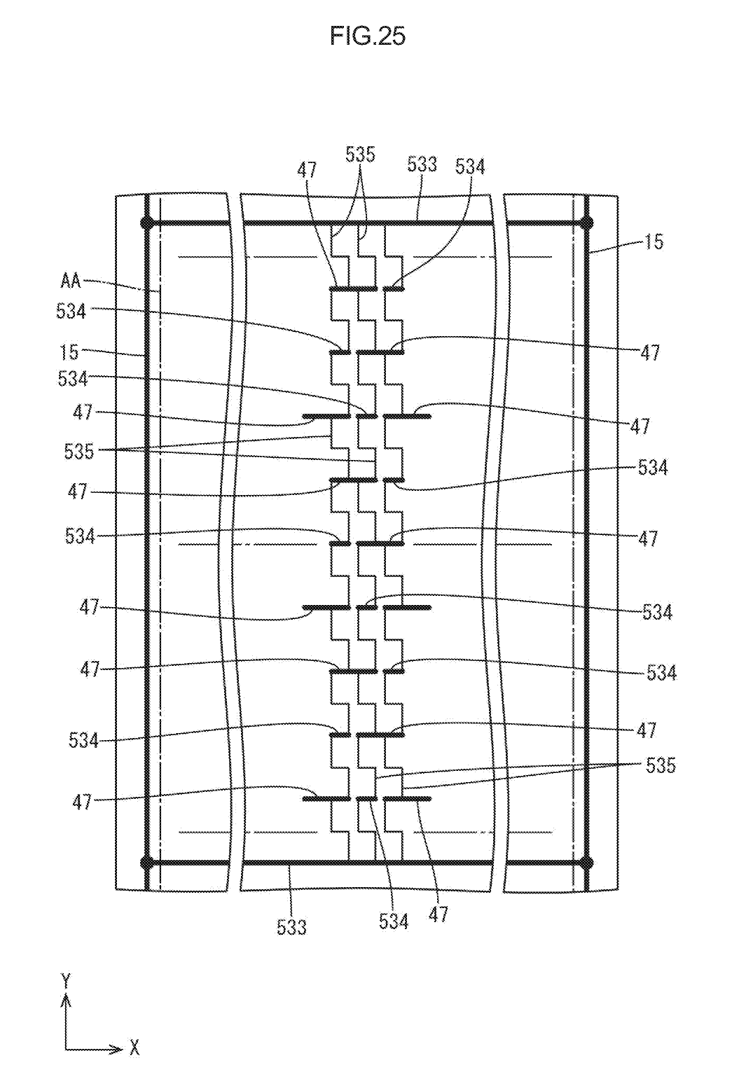

A sixth embodiment of the present technology will be described with reference to FIGS. 24 and 25. In the sixth embodiment, an auxiliary capacitor electrode 534 includes an extended auxiliary capacitor electrode 47 as a part thereof. Configurations, operations, and advantageous effects same as those of the firs embodiment will not be described.

As illustrated in FIG. 24, an array substrate of this embodiment includes auxiliary capacitor lines 533, auxiliary capacitor electrodes 534, auxiliary capacitor connecting sections 535, and extended auxiliary capacitor electrodes (the second auxiliary capacitor) 47. The extended auxiliary capacitor electrode 47 extends in the X-axis direction and overlaps a part of the pixel electrode 517 to create an electrostatic capacitance between the extended auxiliary capacitor electrode 47 and the pixel electrode 517 similar to the auxiliary capacitor electrode 534. The extended auxiliary capacitor electrode 47 overlaps a gate line 518. However, unlike the auxiliary capacitor electrode 534, the extended auxiliary capacitor electrode 47 overlaps one of the two source lines 519 that sandwich the pixel electrode 517 therebetween. Namely, the extended auxiliary capacitor electrode 47 extends between two pixel electrodes 517 that are adjacent to each other while having the source line 519 therebetween and crosses and overlaps the two pixel electrodes 517. The extended auxiliary capacitor electrode 47 is disposed next to the auxiliary capacitor electrode 534 in the X-axis direction and two extended auxiliary capacitor electrodes 47 are not arranged next to each other in the X-axis direction. Similarly, two auxiliary capacitor electrodes 534 are not arranged next to each other in the X-axis direction. The extended auxiliary capacitor electrodes 47 that are next to each other in the Y-axis direction and the auxiliary capacitor electrodes 534 that are next to each other in the Y-axis direction are arranged in an off-set plan view arrangement or a zig-zag plan view arrangement.

In the present embodiment, the number of the auxiliary capacitor lines 533 is smaller than that of the first embodiment because the extended auxiliary capacitor electrodes 47 are disposed. Specifically, as illustrated in FIG. 25, nine rows of the extended auxiliary capacitor electrodes 47 and the auxiliary capacitor electrodes 534 and ten rows of the auxiliary capacitor connecting sections 535 are arranged between the two auxiliary capacitor lines 533 that are arranged in the Y-axis direction. Each of the nine rows includes the extended auxiliary capacitor electrodes 47 and the auxiliary capacitor electrodes 534 arranged in the X-axis direction and each of the ten rows includes the auxiliary capacitor connecting sections 535 arranged in the X-axis direction, in other words, nine rows of the extended auxiliary capacitor electrodes 47 and the auxiliary capacitor electrodes 534 are disposed between the two auxiliary capacitor lines 533 that are arranged in the Y-axis direction, and ten rows of the auxiliary capacitor connecting sections 535 are disposed between the two auxiliary capacitor lines 533 that are arranged in the Y-axis direction. Therefore, the number of the auxiliary capacitor lines 533 is greatly reduced compared to a configuration of the first embodiment in which the auxiliary capacitor lines 33 and the auxiliary capacitor electrodes 34 are arranged alternately in the Y-axis direction (see FIG. 2). Accordingly, the number of the crossing portions of the source lines 519 and the auxiliary capacitor lines 533 is decreased and the parasitic capacitance that may be created between the source lines 519 and the auxiliary capacitor lines 533 can be decreased. Furthermore, the source overlapping line 536 extends between the auxiliary capacitor line 533 and the extended auxiliary capacitor electrode 47 arranged in the Y-axis direction or extends over an area between two extended auxiliary capacitor electrodes 47 that are adjacent to each other in the Y-axis direction. Specifically, as illustrated in FIG. 24, two extended auxiliary capacitor electrodes 47 that are spaced from each other in the Y-axis direction and disposed along the Y-axis direction are periodically arranged so as to have two extended auxiliary capacitor electrodes 47 and two auxiliary capacitor electrodes 534 therebetween. The source overlapping line 536 extends over a range between the two extended auxiliary capacitor electrodes 47 and has an extending length that is about three times of the long-side dimension of the pixel electrode 517. Thus, the creepage distance of the source overlapping line 536 is longer than that of the first embodiment and therefore, a line resistance of the source line 519 is further lowered. Since the extended auxiliary capacitor electrodes 47 and the auxiliary capacitor electrodes 534 are arranged regularly as described above, the reference potential supplied through the auxiliary capacitor line 533 is less likely to be blunted and display errors such as shadowing are less likely to be caused.

As described before, according to this embodiment, the second auxiliary capacitor includes the extended auxiliary capacitor electrode 47 overlapping one of the two source lines 519 in a pair sandwiching the pixel electrode 517 via the first interlayer insulator. According to such a configuration, the extended auxiliary capacitor electrode 47 included in the second auxiliary capacitor is configured to cross the pixel electrode 517 that is next thereto while having one of the two source lines 519. Since the extended auxiliary capacitor electrode 47 is arranged, the number of the auxiliary capacitor lines 533 is decreased and accordingly, the parasitic capacitance that may be caused between the auxiliary capacitor line 533 and the source line 519 can be reduced.

### Seventh Embodiment

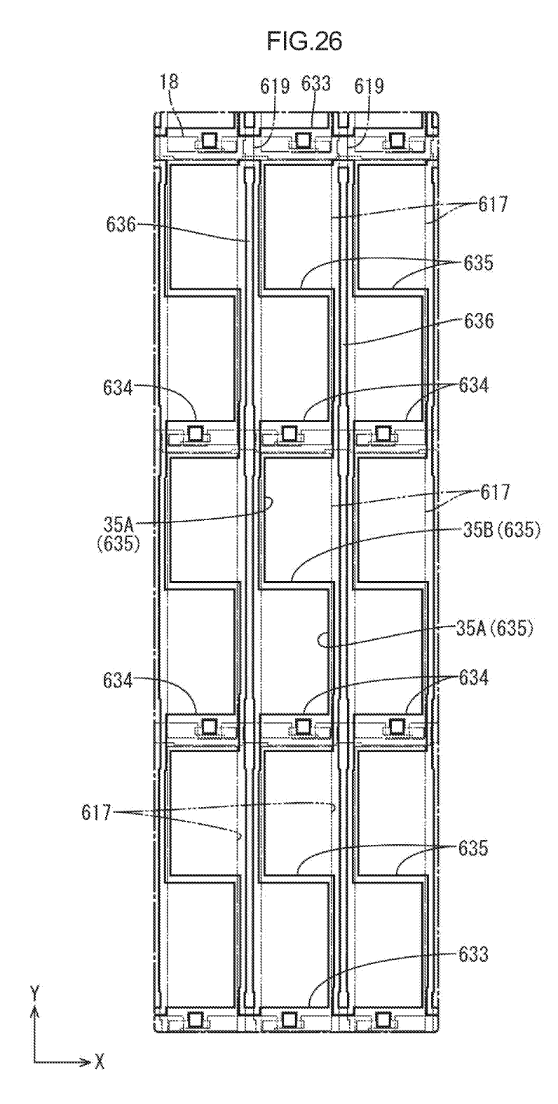

A seventh embodiment of the present technology will be described with reference to FIG. 26. In the seventh embodiment, arrangement of auxiliary capacitor electrodes 634 and auxiliary capacitor connecting sections 635 is different from that of the first embodiment. Configurations, operations, and advantageous effects same as those of the first embodiment will not be described.

As illustrated in FIG. 26, two auxiliary capacitor electrodes 634 and three auxiliary capacitor connecting sections 635 are arranged between the auxiliary capacitor lines 633 that are arraigned next to each other in the Y-axis direction. Therefore, a source overlapping line 636 extends over a range between the two auxiliary capacitor electrodes 634 and has an extending length that is about three times of the long-side dimension of a pixel electrode 617. Thus, a creepage distance of the source overlapping line 636 is longer than that of the first embodiment and therefore, a line resistance of a source line 619 is further lowered.

As described before, according to this embodiment, the auxiliary capacitor lines 633 are arranged at intervals with respect to an extending direction of the source line 619 and the auxiliary capacitor electrodes 634 are arranged at intervals with respect to the extending direction of the source line 619 between the two auxiliary capacitor lines 633 that are arranged in the extending direction of the source line 619. The source overlapping line 636 extends over a range between the two auxiliary capacitor lines 633 that are arranged in the extending direction of the source line 619. According to such a configuration, the short circuit is less likely to be caused between the source overlapping line 636 and the auxiliary capacitor line 633 that is included in the same layer as the source overlapping line 636 and crosses the source line 619. Furthermore, compared to a configuration including only one auxiliary capacitor electrode between the two auxiliary capacitor lines 633, the creepage distance of the source overlapping line 636 is increased. Therefore, the resistance of the source line 619 is preferably lowered.

### Other Embodiments

The technology described herein is not limited to the embodiments described in the above sections and the drawings. For example, the following embodiments may be included in a technical scope.

(1) The auxiliary capacitor lines, the auxiliary capacitor electrode, and the auxiliary capacitor connecting sections may be formed from different metal films. In such a configuration, an insulator disposed between the auxiliary capacitor lines, the auxiliary capacitor electrode, and the auxiliary capacitor connecting sections may have contact holes for connecting them.

(2) Each of the auxiliary capacitor lines, the auxiliary capacitor electrode, and the auxiliary capacitor connecting sections may be formed from a different metal film. The auxiliary capacitor electrode may be formed from a metal film different from that of the auxiliary capacitor line and the auxiliary capacitor connecting section. The auxiliary capacitor line may be formed from a metal film different from that of the auxiliary capacitor electrode and the auxiliary capacitor connecting section.

(3) At least one of the auxiliary capacitor line and the auxiliary capacitor electrode may be configured not to overlap the gate line. If the auxiliary capacitor electrode does not overlap the gate line while the auxiliary capacitor line overlapping the gate line, the auxiliary capacitor electrode overlaps a middle section of the pixel electrode with respect to the long-side dimension thereof. In the sixth and seventh embodiments, the extended auxiliary capacitor electrode may be configured not to overlap the gate line.

(4) The specific arrangement of the auxiliary capacitor connecting sections may be altered from that described in the above embodiments. It is preferable to arrange the auxiliary capacitor connecting sections so as to overlap dark sections that may be locally caused in the pixels according to the display mode.

(5) The polymer sustained alignment (PSA) technology may be applied to the configuration of each of the second to fourth embodiments. The PSA technology is a technique of forming an alignment sustained layer that applies pretilt to the liquid crystal molecules included in the liquid crystal layer in the absence of an applied voltage. The alignment sustained layer is formed by photopolymerizing a photopolymerizable polymer that is previously mixed with the liquid crystal material while the liquid crystal layer being applied with a voltage. In the absence of an applied voltage, the liquid crystal molecules are sustained to be tilted at a pretilt angle and an alignment direction, that is tilted by two to three degrees with respect to a normal line to a substrate surface.

(6) The plan view shape of the holes may be altered from that of the third and fourth embodiments. For example, the hole may have a fishbone plan view shape like the shape of the pixel electrode of the second embodiment.

(7) In the third and fourth embodiments, the CF substrate may include a projection on the surface thereof forming a projection made of derivative between the counter electrode and the alignment film.

(8) The specific arrangement of the auxiliary capacitor lines and the extended auxiliary capacitor electrodes and the specific number of rows of the auxiliary capacitor lines and the extended auxiliary capacitor electrodes that are arranged between the two auxiliary capacitor lines arranged in the Y-axis direction may be altered as appropriate.

(9) In the seventh embodiment, three auxiliary capacitor electrodes may be disposed between the adjacent two auxiliary capacitor lines arranged in the Y-axis direction. According to such a configuration, the creepage distance of the source overlapping line is further increased.

(10) In each of the embodiments, the metal film included in the array substrate may be formed of titanium, molybdenum, and tungsten.

(11) The liquid crystal panel may be a normally-white type in which the liquid crystal panel is in highest gradation display (white display) in the absence of an applied voltage. In such a configuration, a display mode of the liquid crystal panel may be preferably the TN mode.

(12) In each of the above embodiments, the display mode of the liquid crystal panel may be the IPS mode or the FFS mode. A common electrode may be disposed on the array substrate instead of the counter electrode disposed on the CF substrate in the VA mode.

(13) The TFTs may be arranged in a matrix.

(14) The specific screen size or the specific resolution of the liquid crystal panel may be altered as appropriate. The specific arrangement interval between the pixels of the liquid crystal panel may be altered as appropriate.

(15) One driver may be mounted on the array substrate.

(16) The semiconductor film may be made of amorphous silicon. The semiconductor film may be made of polysilicon. In such a configuration, a TFT of a bottom gate type may be preferably used.

(17) The liquid crystal display device may have a plan view shape of a vertically elongated rectangle, a square, a circle, a semi-circle, an oval, an ellipse, or a trapezoid.

(18) The technology described herein may be applied to other types of display panels such as an organic EL panel, an electrophoretic display (EPD) panel of a microcapsule type, and a micro electro mechanical systems (MEMS) display panel.

1. A substrate for a display device comprising:
a pixel electrode;
at least two signal lines sandwiching the pixel electrode, supplying a signal to the pixel electrode, and extending in an extending direction of a signal line;
a first auxiliary capacitor that extends and crosses the pixel electrode and the at least two signal lines, the first auxiliary capacitor overlapping the at least two signal lines via a first interlayer insulator and overlapping the pixel electrode via a second interlayer insulator;
a second auxiliary capacitor disposed spaced from the first auxiliary capacitor with respect to the extending direction of the signal line, the second auxiliary capacitor overlapping the pixel electrode via the second interlayer insulator and not overlapping one of the at least two signal lines; and
an auxiliary capacitor connecting section connecting the first auxiliary capacitor and the second auxiliary capacitor.

2. The substrate according to claim 1, further comprising a scanning line extending and crossing the at least two signal lines, wherein
the first auxiliary capacitor and the second auxiliary capacitor are included in a same layer that is different from a layer of the scanning line.

3. The substrate according to claim 2, wherein the first auxiliary capacitor is disposed such that a part thereof overlaps the scanning line.

4. The substrate according to claim 3, wherein
the pixel electrode includes pixel electrodes and the pixel electrodes are arranged in a display area in a matrix along the extending direction of the signal line and an extending direction of the scanning line,
the first auxiliary capacitor includes first auxiliary capacitors, and
the first auxiliary capacitors are arranged at intervals in the extending direction of the signal line, and a part of the first auxiliary capacitors extends parallel to the scanning line over an entire area of the display area.

5. The substrate according to claim 4, wherein the first auxiliary capacitors are connected to each other via the second auxiliary capacitor and the auxiliary capacitor connecting section.

6. The substrate according to claim 2, wherein the second auxiliary capacitor is arranged such that a part thereof overlaps the scanning line.

7. The substrate according to claim 2, wherein the auxiliary capacitor connecting section is included in a same layer as the first auxiliary capacitor and the second auxiliary capacitor.

8. The substrate according to claim 2, further comprising a signal overlapping line that is included in a same layer as the first auxiliary capacitor and the second auxiliary capacitor and extends parallel to one of the at least two signal lines and a part of which overlaps the one of the at least two signal lines, wherein
the first interlayer insulator that is between the one of the at least two signal lines and the signal overlapping line has a contact hole through which the one of the at least two signal lines and the signal overlapping line are connected to each other.

9. The substrate according to claim 8, wherein the signal overlapping line extends in the extending direction of the signal line while having the second auxiliary capacitor in a middle section thereof.

10. The substrate according to claim 9, wherein
the scanning line includes scanning lines that are arranged at intervals in the extending direction of the signal line and the first auxiliary capacitor partially overlaps one of the scanning lines and the second auxiliary capacitor partially overlaps one of the scanning lines, and
the first interlayer insulator that is between the one of the at least two signal lines and the signal overlapping line has contact holes at positions corresponding two end portions of the signal overlapping line in the extending direction and at two positions sandwiching the second auxiliary capacitor with respect to the extending direction.

11. The substrate according to claim 8, wherein
the first auxiliary capacitor includes first auxiliary capacitors that are arranged at intervals in the extending direction of the signal line and the second auxiliary capacitor includes second auxiliary capacitors that are arranged at intervals in the extending direction of the signal line between two of the first auxiliary capacitors arranged in the extending direction of the signal line, and
the signal overlapping line extends over a range between the two of the first auxiliary capacitors arranged in the extending direction of the signal line.

12. The substrate according to claim 1, wherein the second auxiliary capacitor includes an auxiliary capacitor electrode that does not overlap the at least two signal lines sandwiching the pixel electrode.

13. The substrate according to claim 1, wherein the second auxiliary capacitor includes an extended auxiliary capacitor electrode that overlaps one of the at least two signal lines sandwiching the pixel electrode while having the first interlayer insulator between the extended auxiliary capacitor electrode and the one of the at least two signal lines.

14. The substrate according to claim 1, wherein the auxiliary capacitor connecting section has a plan view shape of point symmetric.

15. A display device comprising:
the substrate according to claim 1; and
a counter substrate that is disposed opposite the substrate.
